(19) United States
(12) Patent Application Publication
(10) Pub. No.: US 2026/0223542 A1
(43) Pub. Date: Jul. 30, 2026

(54) DISPLAY PANEL AND ELECTRONIC DEVICE INCLUDING THE SAME

(71) Applicant: SAMSUNG DISPLAY CO., LTD., Yongin-si (KR)

(72) Inventors: Heerim Song, Yongin-si (KR); Sukyo Jung, Yongin-si (KR); Jaewon Cho, Yongin-si (KR); Heeju Moon, Yongin-si (KR)

(21) Appl. No.: 19/455,027

(22) Filed: Jan. 21, 2026

(30) Foreign Application Priority Data
Jan. 24, 2025 (KR) 10-2025-0011882

(51) Int. Cl. H10K 59/121

(52) U.S. Cl. CPC H10K 59/1213

(57) ABSTRACT

A display panel includes a substrate including a first display area and a second display area, the second display area including a transmission area, a plurality of first pixel circuits and a plurality of first light-emitting diodes arranged in the first display area, a plurality of second pixel circuits arranged in the second display area and each including a first transistor and a second transistor, the first transistor including an oxide semiconductor, and the second transistor including a silicon semiconductor, a plurality of second light-emitting diodes arranged in the second display area and respectively connected to the plurality of second pixel circuits, and a bottom metal layer arranged in the second display area and between the substrate and the second transistor, wherein the bottom metal layer overlaps the second transistor of each of the plurality of second pixel circuits and extends across the second display area in a first direction.

### CROSS-REFERENCE TO RELATED APPLICATIONS

This application is based on and claims priority under 35 U.S.C. § 119 to Korean Patent Application No. 10-2025-0011882 filed on Jan. 24, 2025 in the Korean Intellectual Property Office, the disclosure of which is incorporated by reference herein in its entirety.

### TECHNICAL FIELD

One or more embodiments generally relate to a display panel and an electronic device including the same.

### DISCUSSION OF THE RELATED ART

Recently, display devices have been used for various purposes. As the thicknesses and weights of display devices have decreased, the range of applications of the display devices has increased.

A display device includes a display panel, which includes a display element that implements pixels, and a pixel circuit configured to control electrical signals applied to the display element. The pixel circuit includes a thin-film transistor (TFT), a capacitor, and a plurality of wires.

As display devices are utilized in various manners, various methods for designing the form of display devices may be provided, and the range of functions that may be integrated or linked with the display devices has been expanded.

### SUMMARY

In an embodiment, a display panel and an electronic device including the display panel are provided. The display panel may include a display area that is expanded to display images. The display area may include a component area.

In an embodiment, a display panel includes a substrate including a first display area and a second display area. The second display area includes a transmission area, a plurality of first pixel circuits and a plurality of first light-emitting diodes arranged in the first display area, a plurality of second pixel circuits arranged in the second display area and each including a first transistor and a second transistor. The first transistor including an oxide semiconductor, and the second transistor including a silicon semiconductor such as polycrystalline silicon. A plurality of second light-emitting diodes are arranged in the second display area and respectively connected to the plurality of second pixel circuits. A bottom metal layer is arranged in the second display area and between the substrate and the second transistor. The bottom metal layer overlaps the second transistor of each of the plurality of second pixel circuits and extends across the second display area in a first direction.

The bottom metal layer may include a plurality of sub-bottom metal layers, the plurality of sub-bottom metal layers may be arranged to be spaced apart from each other in a second direction inside the second display area, the second direction may intersect the first direction.

The plurality of sub-bottom metal layers may be connected to each other at an edge of the second display area.

The bottom metal layer may not overlap the first transistor in a plan view.

The plurality of second pixel circuits may be continuously arranged in the second display area in the first direction.

The transmission area may include a plurality of sub-transmission areas, the plurality of second pixel circuits may be alternately arranged with the plurality of sub-transmission areas in a second direction intersecting the first direction.

The first transistor may include a driving transistor, and the second transistor may include an emission control transistor connected to a pixel electrode of each of the plurality of second light-emitting diodes.

The display panel may further include an additional bottom metal layer arranged in the first display area and between the substrate and each of the plurality of first pixel circuits.

The additional bottom metal layer may be provided in a mesh structure connected in the first direction and a second direction in the first display area, the second direction may intersect the first direction.

The plurality of first pixel circuits may each include a first transistor and a second transistor, the additional bottom metal layer may overlap in a plan view the second transistor included in each of the plurality of first pixel circuits, and the second transistor may include the silicon semiconductor.

A display panel includes a substrate including a first display area and a second display area, the second display area includes a transmission area, a plurality of first pixel circuits and a plurality of first light-emitting diodes arranged in the first display area, a plurality of second pixel circuits arranged in the second display area and each including a first transistor and a second transistor, the first transistor including an oxide semiconductor, and the second transistor including a silicon semiconductor, a plurality of second light-emitting diodes arranged in the second display area and respectively connected to the plurality of second pixel circuits, a first bottom metal layer arranged in the first display area and between the substrate and each of the plurality of first pixel circuits, and a second bottom metal layer arranged in the second display area and between the substrate and each of the plurality of second pixel circuits, wherein a shape of the first bottom metal layer is different from a shape of the second bottom metal layer in a plan view.

The second bottom metal layer may overlap the second transistor of each of the plurality of second pixel circuits in a plan view, and the second bottom metal layer may extend across the second display area in a first direction.

The first bottom metal layer may include a horizontal bottom metal layer and a vertical bottom metal layer, the horizontal bottom metal layer may intersect the first display area in the first direction, the vertical bottom metal layer may extend in a second direction intersecting the first direction, and the horizontal bottom metal layer may be continuously arranged with the second bottom metal layer.

The first bottom metal layer may include a plurality of horizontal bottom metal layers and a plurality of vertical bottom metal layers arranged in a mesh structure, the plurality of horizontal bottom metal layers may extend in a first direction, and the plurality of vertical bottom metal layers may extend in a second direction intersecting the first direction.

In an embodiment, each of the plurality of first pixel circuits may include a first transistor and a second transistor, the first transistor may be a silicon semiconductor, the second transistor may be provided as an oxide semiconductor, and each of the plurality of horizontal bottom metal layers may overlap the first transistor of each of the plurality of first pixel circuits.

In an embodiment, an electronic device includes a display panel, and a lower cover forming an exterior of the electronic device and including an opening in a front surface of the lower cover. The opening exposes a portion of the display panel. The display panel includes a substrate including a first display area and a second display area. The second display area includes a transmission area. The display panel also includes a plurality of first pixel circuits and a plurality of first light-emitting diodes arranged in the first display area, a plurality of second pixel circuits arranged in the second display area and each including a first transistor and a second transistor. The first transistor includes an oxide semiconductor, and the second transistor including a silicon semiconductor. The display panel also includes a plurality of second light-emitting diodes arranged in the second display area and respectively connected to the plurality of second pixel circuits. The display panel also includes a bottom metal layer arranged in the second display area and between the substrate and the second transistor. The bottom metal layer overlaps the second transistor of each of the plurality of second pixel circuits and extends across the second display area in a first direction.

The bottom metal layer may include a plurality of sub-bottom metal layers, the plurality of sub-bottom metal layers may be arranged to be spaced apart from each other in a second direction inside the second display area, the second direction may intersect the first direction.

The plurality of sub-bottom metal layers may be connected to each other at an edge of the second display area.

The bottom metal layer may not overlap the first transistor in a plan view.

The electronic device may further include an additional bottom metal layer arranged in the first display area and between the substrate and each of the plurality of first pixel circuits.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view of an electronic device according to an embodiment;

FIG. 2 is an exploded perspective view of an electronic device according to an embodiment;

FIG. 3 is a schematic plan view of a display panel according to an embodiment;

FIG. 4 is a schematic layout view illustrating an arrangement structure of pixels that may be arranged in a first display area, according to an embodiment;

FIG. 5 is a schematic layout view illustrating a pixel arrangement structure in a second display area, according to an embodiment;

FIG. 6 is a plan view of some components of a display panel according to an embodiment;

FIG. 7 is a schematic equivalent circuit diagram of a display element that may be included in a display panel, and a pixel circuit electrically connected to the display element, according to an embodiment;

FIG. 8 is a schematic plan view of pixel circuits that may be arranged on a display panel, according to an embodiment;

FIG. 9 is a schematic cross-sectional view illustrating a portion of a first display area of a display panel, according to an embodiment;

FIG. 10 is a schematic cross-sectional view illustrating a portion of a second display area of a display panel, according to an embodiment;

FIG. 11 is a layout view illustrating the arrangement of a bottom metal layer and some components of a second pixel circuit that may be arranged in a second display area, according to an embodiment;

FIG. 12 is a plan view of a bottom metal layer arranged at a boundary between a first display area and a second display area, according to an embodiment;

FIG. 13 is a layout view illustrating the arrangement of an additional bottom metal layer and some components of a first pixel circuit that may be arranged in a first display area, according to an embodiment;

FIG. 14 is a plan view of a bottom metal layer arranged at a boundary between a first display area and a second display area, according to an embodiment; and

FIG. 15 is a diagram illustrating the electronic device according to an embodiment of the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in detail in the written description. Effects and features of the disclosure, and methods for achieving them will be clarified with reference to embodiments described below in detail with reference to the drawings. However, the disclosure is not necessarily limited to the following embodiments and may be embodied in various forms.

Hereinafter, the disclosure will be described in detail by explaining embodiments of the disclosure with reference to the attached drawings. Like reference numerals in the drawings denote like elements.

It will be understood that, although terms such as “first” and “second” may be used herein to describe various elements, these elements should not be limited by these terms, and these terms are only used to distinguish one element from another.

In the following embodiments, the singular forms include the plural forms unless the context clearly indicates otherwise.

Also, it will be understood that the terms “comprise,” “include,” and “have” used herein specify the presence of stated features or elements, but do not preclude the presence or addition of one or more other features or elements.

It will be further understood that, when a layer, region, or element is referred to as being “on” another layer, region, or element, it can be directly or indirectly on the other layer, region, or element. For example, intervening layers, regions, or elements may be present.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When a certain embodiment may be implemented differently, a specific process order may be performed in the order different from the described order. For example, two processes that are successively described may be performed substantially simultaneously or performed in the order opposite to the order described.

It will be understood that when a layer, region, or element is referred to as being connected to another layer, region, or element, it can be directly or indirectly connected to the other layer, region, or element. For example, intervening layers, regions, or elements may be present. For example, it will be understood that when a layer, region, or element is referred to as being “electrically connected to” or “electrically coupled to” another layer, region, and element, it may be directly or indirectly electrically connected or coupled to the other layer, region, or element. For example, intervening layers, regions, or elements may be present. Moreover, in the accompanying drawings, the thicknesses, ratios, and dimensions of the elements may not be to exact scale and may have been exaggerated for the benefit of effective explanation of the technical features associated with these elements. As such, the present disclosure shall not be restricted to the thicknesses, ratios, dimensions, etc. illustrated in the drawings.

Embodiments of the present disclosure relate to a display panel and an electronic device that includes a first (or “main”) display area and a second (or auxiliary or component) display area. The second display area may include a transparent (or “transmission”) area and pixel circuits. Each pixel circuit may include a plurality of thin film transistors, where some of the thin film transistors include an active area comprised of an oxide semiconductor and others of the thin film transistors include an active layer that is a silicon semiconductor layer. Because the silicon semiconductor layer is sensitive to light, and because the second display area may include a component that transmits or receives electromagnetic radiation, embodiments protect portions of the second display area that are occupied by a silicon semiconductor layer by including a bottom metal layer thereunder. Also the bottom metal layer may be patterned to cover portions of the second display area occupied by a silicon semiconductor layer while omitting the bottom metal layer from beneath another portion. By doing so, electronic stability and high transparency of the display device and electronic device can be simultaneously achieved.

In an embodiment, the transparent area and the bottom metal layer in the second display area may extend from left to right (or “x direction”) in stripes while alternating with one another in an up and down or y direction. Also, edges of the second display area may include a bottom connection line connecting together all of the bottom metal layers extending in the x direction.

In an embodiment, the first display area may also include a bottom metal layer to correspond to channel regions of silicon semiconductor layers while exposing other portions of the first display area. In the first display area and unlike the second display area, the bottom metal layer may have a mesh structure including vertical extending and horizontal extending portions to produce a mesh pattern. The horizontal portions of the bottom metal layer in the first display area may align with the bottom metal layer in the second display area. As a result, channel portions of thin film transistors having a silicon semiconductor layer may be shielded from light while a majority of the display area remains transmissive.

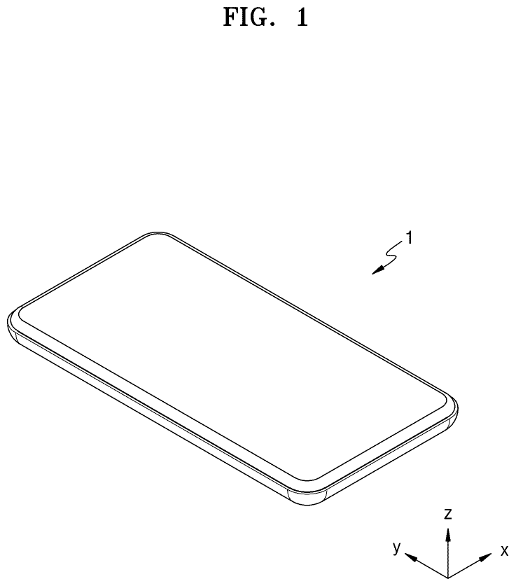

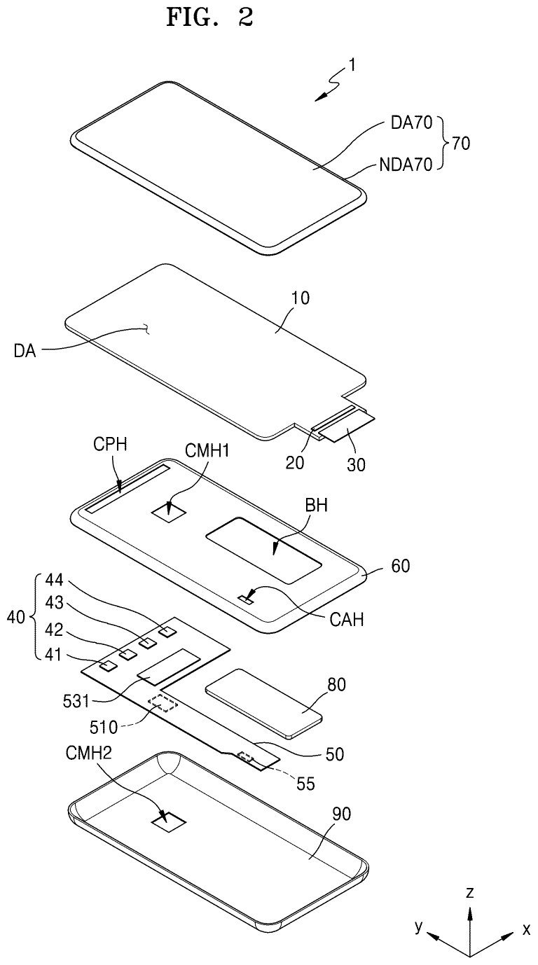

FIG. 1 is a perspective view of an electronic device 1 according to an embodiment, and FIG. 2 is an exploded perspective view of the electronic device 1 according to an embodiment.

FIGS. 1 and 2 illustrate that the electronic device 1 according to an embodiment is a smartphone. The electronic device 1 according to an embodiment may include a cover window 70, a display panel 10, a data driver 20, a display circuit board 30, a component 40, a bracket 60, a main circuit board 50, a battery 80, and a lower cover 90. The electronic device 1 may include an under panel camera (UPC) display device.

In the present specification, “left”, “right”, “up”, and “down” in a plan view indicate directions when viewing the display panel 10 from a vertical direction of the display panel 10. For example, “left” indicates a −x direction, “right” indicates a +x direction, “up” indicates a +y direction, and “down” indicates a −y direction. Herein, “a plan view” of a structure refers to a view from a remote point from a major surface of the structure.

The electronic device 1 may have a rectangular shape on a plane. For example, the electronic device 1 may have a rectangular shape in a plan view having short sides in an x-direction and long sides in a y-direction, as shown in FIG. 1. A corner where a short side in the x-direction meets a long side in the y-direction may be round to have a certain curvature or may be formed at a right angle. However, the shape in a plan view of the electronic device 1 is not necessarily limited to a rectangular shape, and the electronic device 1 may have another shape, such as a polygonal, oval, or irregular shape.

The cover window 70 may be arranged on the display panel 10 and cover the upper surface of the display panel 10. Accordingly, the cover window 70 may protect the upper surface of the display panel 10.

The cover window 70 may include a transparent cover portion DA70 corresponding to the display panel 10, and a light-shielding cover portion NDA70 surrounding the transparent cover portion DA70. The light-shielding cover portion NDA70 may include an opaque material (e.g., a colored opaque material) that blocks light. The light-shielding cover portion NDA70 may include a pattern that may be displayed to a user when an image is not displayed.

The display panel 10 provides an image and may be arranged below the cover window 70. The display panel 10 may overlap the transparent cover portion DA70 of the cover window 70.

The display panel 10 includes a display area DA. The display area DA is an area where an image is displayed, and the display area DA may include an area (hereinafter referred to as a component area) that transmits light emitted from the component 40 arranged below the display panel 10. The component 40 may include a sensor using visible light, infrared rays, or sound, a camera, or the like.

The display panel 10 displays (or “outputs”) information processed by the electronic device 1. For example, the display panel 10 may display execution screen information about an application running on the electronic device 1, or user interface (UI) or graphical user interface (GUI) information according to the execution screen information.

The display panel 10 may include a light-emitting display panel including a light-emitting diode (LED). The LED may include an organic LED including an organic emission layer. In some embodiments, the LED may include an inorganic LED including an inorganic material. The inorganic LED may include a PN junction diode including inorganic semiconductor-based materials. When a voltage is applied to the PN junction diode in a forward direction, holes and electrons are injected, and energy generated by recombination of the holes and the electrons is converted into light energy such that light of a certain color may be emitted. The aforementioned inorganic LED may have a width of several to several hundred micrometers, and in some embodiments, the inorganic LED may be referred to as a micro LED.

As described above, the display panel 10 may include a rigid display panel that has strength and thus is not easily bent, or a flexible display panel that has flexibility and thus is bendable, foldable, or rollable. For example, the display panel 10 may include a foldable display panel that may be folded or unfolded, a curved display panel having a curved display surface, a bendable display panel in which areas other than a display surface are bent, a rollable display panel that may be rolled or unrolled, or a stretchable display panel that may be stretched.

The display panel 10 may include a transparent display panel that is implemented transparently and allows objects or backgrounds arranged on the lower surface of the display panel 10 to be seen from the upper surface of the display panel 10. Alternatively, the display panel 10 may include a reflective display panel that may reflect the objects or backgrounds on the upper surface of the display panel 10.

The data driver 20 may be arranged on the display panel 10 in the form of an integrated circuit (IC). In an embodiment, the data driver 20 may be arranged over the display circuit board 30.

The display circuit board 30 may be attached to one side of the display panel 10. The display circuit board 30 may include a flexible printed circuit board (FPCB) that is bendable, a rigid printed circuit board (PCB) that is hard and thus is not easily bendable, or a composite PCB including both a rigid PCB or an FPCB.

In an embodiment, a touch sensor driver may be arranged over the display circuit board 30. The touch sensor driver may be formed as an IC. The touch sensor driver may be attached to the display circuit board 30. The touch sensor driver may be electrically connected to touch electrodes of a touch screen layer of the display panel 10 through the display circuit board 30.

The touch screen layer of the display panel 10 may detect a touch input from a user by using at least one of various methods, such as a resistive film method and an electrostatic capacitance method. For example, when the touch screen layer of the display panel 10 detects the touch input from the user by using the electrostatic capacitance method, the touch sensor driver may determine whether the user has touched, by applying driving signals to driving electrodes among the touch electrodes and detecting voltages charged in mutual electrostatic capacitance (hereinafter referred to as mutual capacitance) between the driving electrodes and sensing electrodes through the sensing electrodes among the touch electrodes. A user's touch may include a contact touch and a proximity touch. The contact touch refers to direct contact of a user's finger or an object, such as a pen, to the cover window 70 on the touch screen layer. The proximity touch refers to a state in which a user's finger or an object, such as a pen, is arranged close to the cover window 70, such as hovering. The touch sensor driver may transmit sensor data to a main processor 510 according to the detected voltages, and the main processor 510 may calculate touch coordinates where a touch input has occurred by analyzing the sensor data.

A controller configured to supply driving voltages to drive pixels of the display panel 10, a gate driver, and the data driver 20 may be arranged over the display circuit board 30.

A bracket 60 configured to support the display panel 10 may be arranged below the display panel 10. The bracket 60 may include plastic, a metal, or both plastic and a metal. A first camera hole CMH1 into which a camera apparatus 531 is inserted, a battery hole BH in which the battery 80 is arranged, and a cable hole CAH through which a cable connected to the display circuit board 30 passes may be formed in the bracket 60. A component hole CPH overlapping the display panel 10 may be provided in the bracket 60. The component hole CPH may overlap the component 40 of the main circuit board 50 in a third direction (z-direction). In an embodiment, the display area DA of the display panel 10 may overlap the component 40 of the main circuit board 50 in the third direction (z-direction). In an embodiment, the component hole CPH may not be formed in the bracket 60.

In an embodiment, the component 40 may include first to fourth components 41, 42, 43, and 44 overlapping the display panel 10. The first to fourth components 41, 42, 43, and 44 may each be provided as a proximity sensor, an illuminance sensor, an iris sensor, a facial recognition sensor, and a camera (or “image sensor”). The proximity sensor using infrared rays may detect an object arranged close to the upper surface of the electronic device 1, and the illuminance sensor may detect the brightness of light incident on the upper surface of the electronic device 1. Also, the iris sensor may capture an image of a person's iris above the upper surface of the electronic device 1, and the camera may capture an image of an object arranged on the upper surface of the electronic device 1. However, the component 40 is not necessarily limited to the proximity sensor, the illuminance sensor, the iris sensor, the facial recognition sensor, and the camera, and various other sensors may be arranged.

The main circuit board 50 and the battery 80 may be arranged below the bracket 60. The main circuit board 50 may include a PCB or an FPCB.

The main circuit board 50 may include the main processor 510, the camera apparatus 531, a main connector 55, and the component 40. The main processor 510 may be formed as an IC. The camera apparatus 531 may be arranged on both the upper surface and the lower surface of the main circuit board 50, and each of the main processor 510 and the main connector 55 may be arranged on either the upper surface or the lower surface of the main circuit board 50.

The main processor 510 may control all functions of the electronic device 1. For example, the main processor 510 may output digital video data to the data driver 20 through the display circuit board 30 so that the display panel 10 displays an image. The main processor 510 may receive an input of detection data from the touch sensor driver. The main processor 510 may determine whether the user has touched based on the detection data, and execute an operation corresponding to a direct touch or a proximity touch of the user. The main processor 510 may include an application processor, a central processing unit, or a system chip, which is formed as an IC.

The camera apparatus 531 processes an image frame, such as a still image or a video, obtained by an image sensor in a camera mode and outputs the same to the main processor 510. The camera apparatus 531 may include at least one of a camera sensor (e.g., a charge-coupled device (CCD) or a complementary metal-oxide-semiconductor (CMOS)), a photosensor (or “image sensor”), and a laser sensor. The camera apparatus 531 may be connected to the image sensor of the component 40 and process an image input to the image sensor, the image sensor overlapping a second display area DA2.

A cable passing through the cable hole CAH of the bracket 60 may be connected to the main connector 55, and accordingly, the main circuit board 50 may be electrically connected to the display circuit board 30.

The battery 80 may be arranged not to overlap the main circuit board 50 in the third direction (z-direction). The battery 80 may overlap the battery hole BH of the bracket 60.

The lower cover 90 may form the exterior of the electronic device 1 and include an opening in the front surface thereof, the opening exposing a portion of the display panel 10. The lower cover 90 has a shape in which a surface corresponding to the display panel 10 is open, and may be assembled with the display panel 10. The lower cover 90 may be arranged on the opposite side of the cover window 70 with the display panel 10 therebetween. The lower cover 90 may be arranged below the main circuit board 50 and the battery 80. The lower cover 90 may be fastened and fixed to the bracket 60. The lower cover 90 may form the lower exterior of the electronic device 1. The lower cover 90 may include plastic, a metal, or both plastic and a metal.

A second camera hole CMH2 through which the lower surface of the camera apparatus 531 is exposed may be formed in the lower cover 90. The position of the camera apparatus 531 and positions of the first and second camera holes CMH1 and CMH2 corresponding to the camera apparatus 531 are not necessarily limited to the embodiments shown in FIGS. 1 and 2 and may vary.

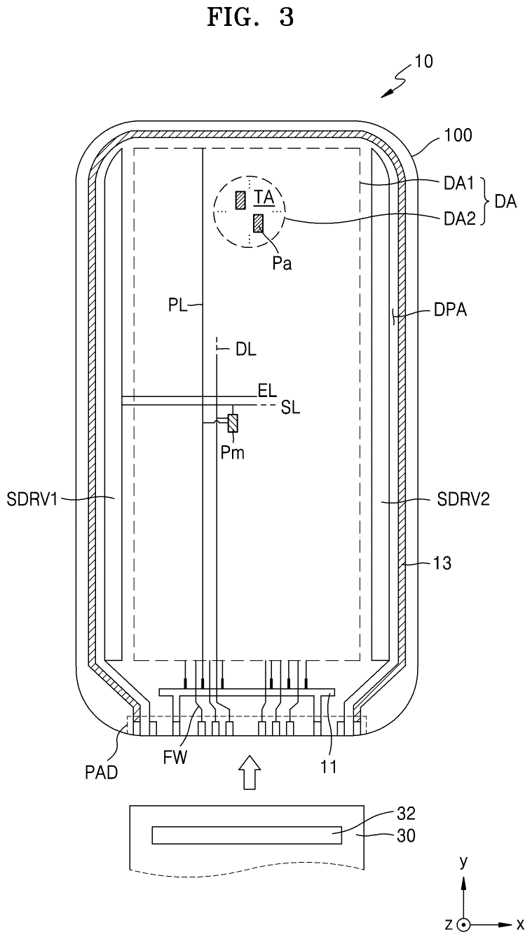

FIG. 3 is a schematic plan view of a display panel 10 according to an embodiment.

Referring to FIG. 3, various components of the display panel 10 are arranged over a substrate 100. The substrate 100 includes a display area DA and a peripheral area DPA surrounding the display area DA. The display area DA includes a first display area DA1 in which a main image is displayed, and a second display area DA2 that includes a transparent area (or “transmission area”) TA and on which an auxiliary image is displayed. The auxiliary image may form a single complete image together with the main image, or the auxiliary image may be independent from the main image.

A plurality of main subpixels Pm are arranged in the first display area DA1. The main subpixels Pm may each be implemented as a display element, such as an organic LED. Each of the main subpixels Pm may emit, for example, red, green, blue, or white light. The first display area DA1 may be covered by an encapsulation member and protected from external air or moisture.

The second display area DA2 may be an area that overlaps a component, such as a camera or a sensor, arranged below the display panel 10. The second display area DA2 may be arranged inside the display area DA and may be surrounded by the first display area DA1. Alternatively, the second display area DA2 may be arranged on one side of the first display area DA1. A plurality of auxiliary subpixels Pa are arranged in the second display area DA2. Each of the plurality of auxiliary subpixels Pa may each be implemented by a display element, such as an organic LED. Each of the auxiliary subpixels Pa may emit, for example, red, green, blue, or white light. The second display area DA2 may be covered by an encapsulation member and protected from external air or moisture.

In addition, the second display area DA2 may include the transparent area TA through which light is transmitted. The transparent area TA may be an area of the second display area DA2 where the auxiliary subpixels Pa are not arranged. The transparent area TA may be surrounded by the plurality of auxiliary subpixels Pa or may be alternately arranged with the plurality of auxiliary subpixels Pa.

Because the second display area DA2 includes the transparent area TA, the resolution of the second display area DA2 may be lower than the resolution of the first display area DA1. However, one or more embodiments are not necessarily limited thereto. The resolution of the second display area DA2 may be the same as the resolution of the first display area DA1.

Each of pixel circuits configured to drive the subpixels Pm and Pa may be electrically connected to peripheral circuits arranged in the peripheral area DPA. A first scan driving circuit SDRV1, a second scan driving circuit SDRV2, a terminal portion PAD, a driving voltage supply line 11, and a common voltage supply line 13 may be arranged in the peripheral area DPA.

The first scan driving circuit SDRV1 may be configured to apply a scan signal to each of the pixel circuits configured to drive the subpixels Pm and Pa through a scan line SL. The first scan driving circuit SDRV1 may be configured to apply an emission control signal to each of the pixel circuits through an emission control line EL. The second scan driving circuit SDRV2 may be arranged on the opposite side of the first display area DA1 with the first scan driving circuit SDRV1 as the center and may be approximately parallel to the first scan driving circuit SDRV1. Some of the pixel circuits of the main subpixels Pm of the first display area DA1 may be electrically connected to the first scan driving circuit SDRV1, and others thereof may be electrically connected to the second scan driving circuit SDRV2. Some of the pixel circuits of the auxiliary subpixels Pa of the second display area DA2 may be electrically connected to the first scan driving circuit SDRV1, and others thereof may be electrically connected to the second scan driving circuit SDRV2. The second scan driving circuit SDRV2 may be omitted.

The terminal portion PAD may be arranged on one side of the substrate 100. The terminal portion PAD is exposed without being covered by an insulating layer and is connected to a display circuit board 30. A display driver 32 may be arranged in the display circuit board 30.

The display driver 32 may be configured to generate a control signal transmitted to the first scan driving circuit SDRV1 and the second scan driving circuit SDRV2. The display driver 32 may be configured to generate a data signal, and the generated data signal may be transmitted to the pixel circuits of the subpixels Pm and Pa through a fan-out wire FW and a data line DL connected to the fan-out wire FW.

The display driver 32 may be configured to supply a driving voltage ELVDD to the driving voltage supply line 11 and supply a common voltage ELVSS to the common voltage supply line 13. The driving voltage ELVDD may be applied to the pixel circuits of the subpixels Pm and Pa through a driving voltage line PL connected to the driving voltage supply line 11, and the common voltage ELVSS may be applied to an opposite electrode of a display element through the common voltage supply line 13.

The driving voltage supply line 11 may extend in an x-direction from the lower side of the first display area DA1. The common voltage supply line 13 may have a loop shape having one side open and partially surround the first display area DA1.

Although FIG. 3 illustrates only one second display area DA2, a plurality of second display areas DA2 may be provided. In this case, the plurality of second display areas DA2 are arranged to be spaced apart from each other, and a first camera may be arranged to correspond to one second display area DA2, while a second camera may be arranged to correspond to another second display area DA2. Alternatively, the camera may be arranged to correspond to one second display area DA2, while an infrared sensor may be arranged to correspond to another second display area DA2. The shapes and sizes of the plurality of second display areas DA2 may be provided differently.

Moreover, the second display area DA2 may be provided in a polygonal shape. For example, the second display area DA2 may be provided in an octagonal shape. The second display area DA2 may be provided in various polygonal shapes, such as a quadrangular shape and a hexagonal shape.

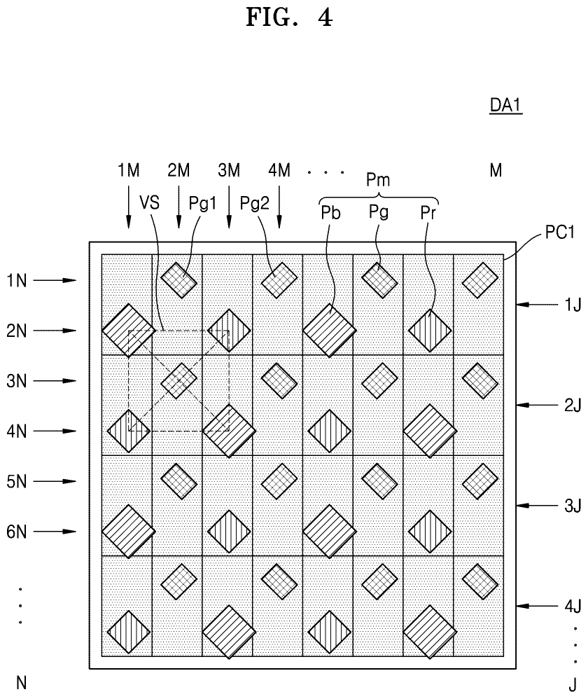

FIG. 4 is a schematic layout view illustrating an arrangement structure of pixels that may be arranged in a first display area DA1, according to an embodiment.

The plurality of main subpixels Pm may be arranged in the first display area DA1. In the present specification, a subpixel is the smallest unit that implements an image and refers to an emission area. In addition, when an organic LED is used as a display element, the emission area may be defined by an opening of a pixel-defining layer.

In the first display area DA1, first pixel circuits PC1 configured to respectively drive the main subpixels Pm may be arranged below the plurality of main subpixels Pm.

The main subpixels Pm arranged in the first display area DA1 may be arranged in a PENTILE™ structure. A red subpixel Pr, a green subpixel Pg, and a blue subpixel Pb may implement red, green, and blue, respectively.

The red subpixel Pr and the blue subpixel Pb may be provided in a rhombus shape. The green subpixel Pg may be provided in a rectangular shape and may include a first green subpixel Pg1 of which a long side is oriented at −45 degrees with respect to the x-direction, and a second green subpixel Pg2 of which a long side is oriented at +45 degrees with respect to the x-direction.

A plurality of first green subpixels Pg1 and a plurality of second green subpixels Pg2 may be alternately arranged in a first row 1N. A plurality of blue subpixels Pb and a plurality of red subpixels Pr may be alternately arranged in a second row 2N adjacent to the first row 1N. A plurality of second green subpixels Pg2 and a plurality of first green subpixels Pg1 may be alternately arranged in a third row 3N adjacent to the second row 2N. Red subpixels Pr and blue subpixels Pb may be alternately arranged in a fourth row 4N adjacent to the third row 3N, and this arrangement of pixels may be repeated up to an N-th row. In this case, the blue subpixel Pb and the red subpixel Pr may be provided in greater sizes than the green subpixel Pg.

The plurality of green subpixels Pg arranged in the first row 1N and the plurality of red subpixels Pr and the plurality of blue subpixels Pb arranged in the second row 2N are alternately arranged. Accordingly, blue subpixels Pb and red subpixels Pr may be alternately arranged in a first column 1M, a plurality of first green subpixels Pg1 and a plurality of second green subpixels Pg2 may be alternately arranged in an adjacent second column 2M, red subpixels Pr and blue subpixels Pb may be alternately arranged in an adjacent third column 3M, and a plurality of second green subpixel Pg2 and a plurality of first green subpixels Pg1 may be alternately arranged in an adjacent fourth column 4M. This arrangement of pixels are repeated up to an M-th column.

When this pixel arrangement structure is expressed in other words, blue subpixels Pb may be arranged at first and third vertices, which are opposite to each other, among vertices of a virtual square VS that uses the center point of the green subpixel Pg as the center point thereof, and red subpixels Pr may be arranged at second and fourth vertices, which are the remaining vertices. In this case, the virtual square VS may be transformed into various shapes, such as a rectangular shape, a rhombus shape, and a square shape.

This pixel arrangement structure is referred to as a PenTile™ structure, and by applying a rendering drive method that shares adjacent pixels to express colors, high resolution may be achieved with fewer pixels.

Although FIG. 4 illustrates that the plurality of main subpixels Pm are arranged in a PenTile™ structure, one or more embodiments are not necessarily limited thereto. For example, the plurality of main subpixels Pm may be arranged in various shapes, such as a stripe structure, a mosaic arrangement structure, and a delta arrangement structure.

The first pixel circuits PC1 may overlap the main subpixels Pm and may be arranged in a matrix structure of J rows and M columns. One row of the first pixel circuits PC1 may correspond to two rows of the main subpixels Pm. For example, a first row 1J of the first pixel circuits PC1 may correspond to the first row 1N and the second row 2N of the main subpixels Pm. A second row 2J of the first pixel circuits PC1 may correspond to the third row 3N and the fourth row 4N of the main subpixels Pm. Moreover, one column of the first pixel circuits PC1 may correspond to one column of the main subpixels Pm. A first column 1M of the first pixel circuits PC1 may correspond to the first column 1M of the main subpixels Pm.

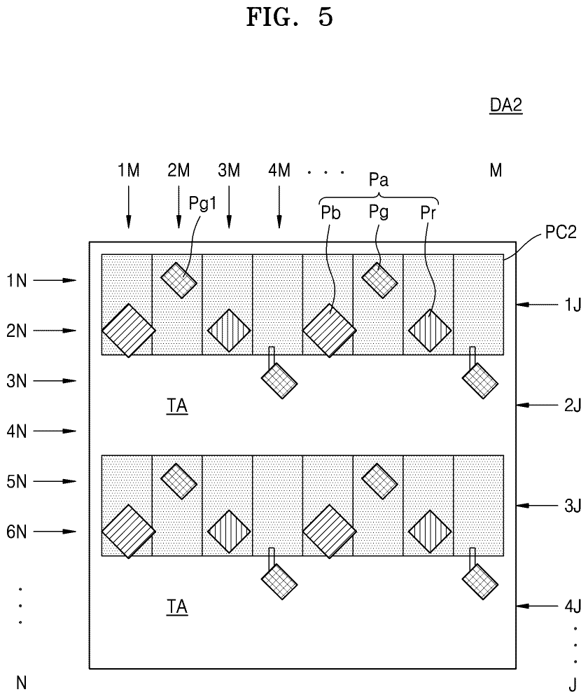

FIG. 5 is a schematic layout view illustrating a pixel arrangement structure in a second display area DA2, according to an embodiment.

Referring to FIG. 5, the plurality of auxiliary subpixels Pa may be arranged in the second display area DA2. Each of the auxiliary subpixels Pa may emit any one of red, green, blue, and white light. The auxiliary subpixels Pa may include a red subpixel Pr, a green subpixel Pg, and a blue subpixel Pb. Also, the transparent area TA may be arranged in the second display area DA2. The transparent area TA may refer to an area where no light-absorbing or light-reflecting metal members are arranged, and thus, high light transmittance is exhibited.

The number per unit area of auxiliary subpixels Pa arranged in the second display area DA2 may be half the number per unit area of main subpixels Pm arranged in the first display area DA1.

In the second display area DA2, a plurality of first green subpixels Pg1 are arranged at a certain interval in a first row 1N. Second green subpixels Pg2 are not arranged. A plurality of blue subpixels Pb and a plurality of red subpixels Pr may be alternately arranged in a second row 2N. In a third row 3N, a plurality of first green subpixels Pg1 are arranged at a certain interval to be misaligned with the first green subpixels Pg1 arranged in the first row 1N. Auxiliary subpixels Pa may not be arranged in a fourth row 4N. This pixel arrangement is repeated up to an N-th row.

A plurality of blue subpixels Pb may be arranged in a first column 1M with a transparent area TA therebetween, first green subpixels Pg1 may be arranged in a second column 2M with the transparent area TA therebetween, a plurality of red subpixels Pr may be arranged in a third column 3M with the transparent area TA therebetween, and first green subpixels Pg1 may be arranged in a fourth column 4M with the transparent area TA therebetween. This pixel arrangement is repeated up to an M-th column. In the second display area DA2, the auxiliary subpixels Pa may be arranged in a “W” the shape.

A plurality of second pixel circuits PC2 may be continuously arranged in a first row 1J and a third row 3J. The plurality of second pixel circuits PC2 may not be arranged in a second row 2J and a fourth row 4J. This arrangement may be repeated up to a J-th row.

In the second display area DA2, the plurality of second pixel circuits PC2 may be continuously arranged in the x-direction, and the plurality of second pixel circuits PC2 may be alternately arranged with transparent areas TA in the y-direction.

Most of the plurality of second pixel circuits PC2 may overlap the auxiliary subpixels Pa. However, some of the auxiliary subpixels Pa may not overlap the second pixel circuits PC2. For example, a green subpixel Pg arranged in the third row 3N and the fourth column 4M may not overlap a second pixel circuit PC2.

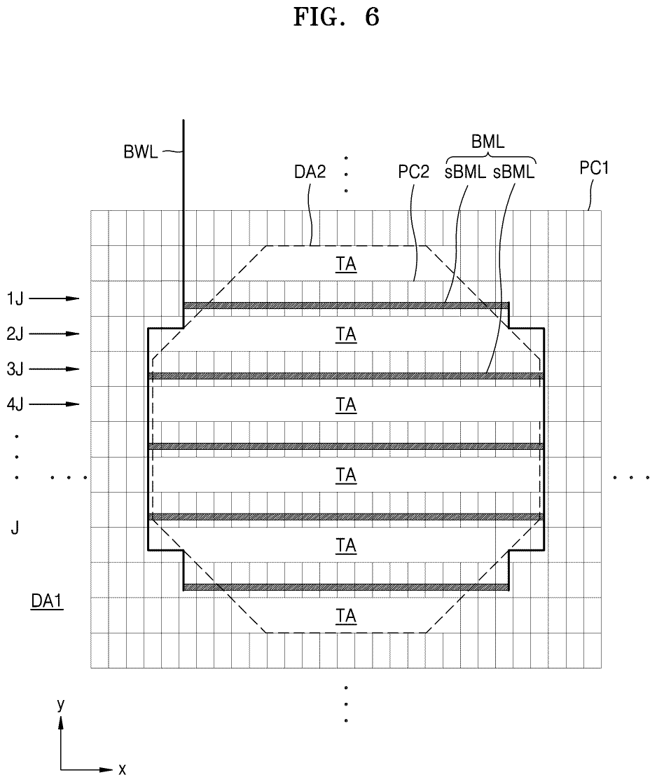

FIG. 6 is a plan view of some components of a display panel according to an embodiment. In detail, FIG. 6 illustrates pixel circuits and a bottom metal layer arranged in a second display area and a first display area therearound.

Referring to FIG. 6, in the first display area DA1, the plurality of first pixel circuits PC1 may be arranged in a matrix form in the x-direction and the y-direction. The plurality of second pixel circuits PC2 and the transparent areas TA may be arranged in the second display area DA2.

The second display area DA2 may be surrounded by the first display area DA1. The second display area DA2 may be provided in various shapes, such as a polygonal shape, a circular shape, and an elliptical shape. FIG. 6 illustrates that the second display area DA2 is provided in an octagonal shape.

In the second display area DA2, the plurality of second pixel circuits PC2 may be continuously arranged in a first direction (x-direction). Also, in the second display area DA2, the plurality of second pixel circuits PC2 may be alternately arranged with the transparent areas TA in a second direction (y-direction) intersecting the first direction.

When the first display area DA1 and the second display area DA2 are seen as a whole, the first pixel circuits PC1 and the second pixel circuits PC2 may be continuously arranged to correspond to the first row 1J. The first pixel circuits PC1 may be arranged parallel to the transparent area TA of the second display area DA2 to correspond to the second row 2J. Next, the first pixel circuits PC1 and the second pixel circuits PC2 may be continuously arranged to correspond to the third row 3J. Next, the first pixel circuits PC1 may be arranged parallel to the transparent area TA of the second display area DA2 to correspond to the fourth row 4J. This arrangement may be continuously repeated up to the end of the second display area DA2.

In addition, a bottom metal layer BML overlapping the plurality of second pixel circuits PC2 may be arranged in the second display area DA2. The bottom metal layer BML may be provided to stabilize the second pixel circuits PC2 from external light by overlapping some of the components included in the second pixel circuits PC2.

The bottom metal layer BML may be arranged in the second display area DA2 and arranged to intersect the second display area DA2 in the first direction (x-direction). The bottom metal layer BML may include a plurality of sub-bottom metal layers sBML. The sub-bottom metal layers sBML may be provided to extend in the first direction (x-direction) inside the second display area DA2. The plurality of sub-bottom metal layers sBML may be arranged to be spaced apart from each other at a certain interval in the second direction (y-direction). The plurality of sub-bottom metal layers sBML may be connected to each other by a bottom connection line BWL at the edge of the second display area DA2. The bottom connection line BWL and the bottom metal layer BML may be arranged on the same layer and integrally provided as a single body. The bottom connection line BWL may extend to a peripheral area of the display panel and receive a constant voltage or a signal.

The total area of the bottom metal layer BML arranged in the second display area DA2 may be smaller than the total area occupied by the second pixel circuits PC2. For example, a width of a sub-bottom metal layer sBML in the y-direction may be less than a width of the second pixel circuit PC2 in the y-direction. The bottom metal layer BML is to block light, and when the area of the bottom metal layer BML is large, the light transmittance of the second display area DA2 may be reduced.

In the present embodiment, the bottom metal layer BML may be arranged to overlap some of the components of the second pixel circuits PC2, thereby stabilizing the second pixel circuits PC2 and simultaneously securing the maximum light transmittance of the second display area DA2. By shielding channel portions of silicon semiconductor layers from light by including the bottom metal layer BML while designing the bottom metal layer BML to not overlap other portions of the second display area DA2, both electronic stability and high luminance can both be achieved.

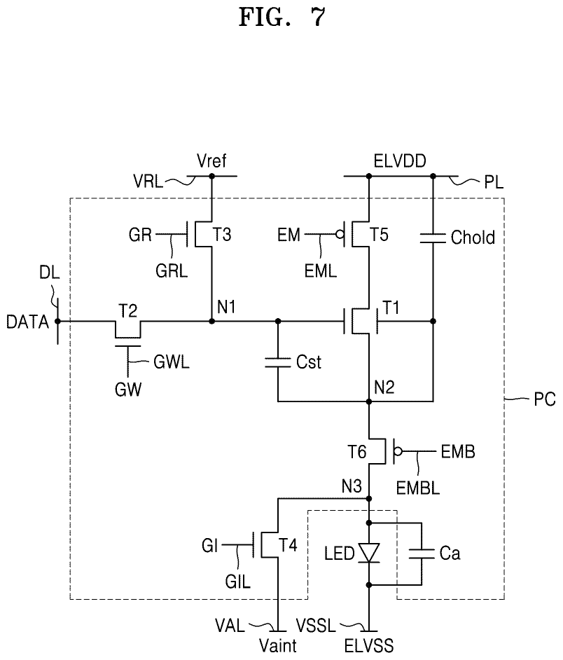

FIG. 7 is a schematic equivalent circuit diagram of a display element that may be included in a display panel, and a pixel circuit PC electrically connected to the display element, according to an embodiment. The display element may include a light-emitting diode LED.

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GIL configured to transmit a fourth gate signal GI, a fifth gate line EMBL configured to transmit a fifth gate signal EMB, and a data line DL configured to transmit a data signal DATA. Because light emission of the light-emitting diode LED is controlled by the third gate signal EM and the fifth gate signal EMB, the third gate signal EM and the fifth gate signal EMB may be referred to as emission control signals, and the third gate line EML and the fifth gate line EMBL may be referred to as emission control lines. The pixel circuit PC may be electrically connected to the driving voltage line PL configured to transmit the driving voltage ELVDD, a reference voltage line VRL configured to transmit a reference voltage Vref, and an initialization voltage line VAL configured to transmit an initialization voltage Vaint.

In an embodiment, some of a plurality of transistors included in the pixel circuit PC may be N-type transistors, and the others may be P-type transistors. First to fourth transistors T1, T2, T3, and T4 may be N-type transistors, and fifth and sixth transistors T5 and T6 may be P-type transistors. Semiconductor layers of the first to fourth transistors T1, T2, T3, and T4 may include a different material from semiconductor layers of the fifth and sixth transistors T5 and T6. In some embodiments, the first to fourth transistors T1, T2, T3, and T4 may include an oxide semiconductor material, and the fifth and sixth transistors T5 and T6 may include amorphous silicon, polysilicon, or an organic semiconductor. Herein, an oxide semiconductor may be a material composed of a metal oxide that exhibits semiconductor properties.

The pixel circuit PC may include the first to sixth transistors T1, T2, T3, T4, T5, and T6, a storage capacitor Cst, a hold capacitor Chold, and an auxiliary capacitor Ca. The first transistor T1 may be a driving transistor configured to output a driving current corresponding to the data signal DATA, and the second to sixth transistors T2, T3, T4, T5, and T6 may be switching transistors configured to transmit a signal. The first transistor T1 may be referred to as a driving transistor, the second transistor T2 may be referred to as a data writing transistor, the third transistor T3 may be referred to as a compensation transistor, the fourth transistor T4 may be referred to as an initialization transistor, the fifth transistor T5 may be referred to as an operation control transistor, and the sixth transistor T6 may be referred to as an emission control transistor.

A first terminal (or “first electrode”) and a second terminal (or “second electrode”) of each of the first to sixth transistors T1, T2, T3, T4, T5, and T6 may be a source (or source electrode) or a drain (or drain electrode) according to voltages of the first terminal and the second terminal. For example, according to the voltages of the first terminal and the second terminal, the first terminal may be a drain and the second terminal may be a source, or the first terminal may be a source and the second terminal may be a drain. Hereinafter, a node to which a first-1 gate electrode of the first transistor T1 is connected may be defined as a first node N1, and a node to which a second terminal of the first transistor T1 is connected may be defined as a second node N2.

The first transistor T1 may be connected to the light-emitting diode LED of the driving voltage line PL. The first transistor T1 may be connected between the fifth transistor T5 and the sixth transistor T6. The first transistor T1 may include a first gate (or “first gate electrode”), a first terminal, and a second terminal connected to the second node N2. The first transistor T1 may include a first-1 gate connected to the first node N1. The first transistor T1 may further include a first-2 gate connected to the second terminal thereof. The first-1 gate and the first-2 gate may be arranged on different layers to face each other. For example, the first-1 gate and the first-2 gate of the first transistor T1 may face each other with a semiconductor layer thereof. In the present specification, the first gate (or “first gate electrode”) of the first transistor T1 may refer to the first-1 gate (or “first-1 gate electrode”) involved in turning on and turning off the first transistor T1.

A gate (or “first-1 gate”) of the first transistor T1 may be connected to a second terminal of the second transistor T2, a first terminal of the third transistor T3, and the storage capacitor Cst. The first-2 gate of the first transistor T1 may be connected to a first terminal of the sixth transistor T6, the storage capacitor Cst, and the hold capacitor Chold. The first terminal of the first transistor T1 may be connected to the driving voltage line PL via the fifth transistor T5, and the second terminal thereof may be connected to a pixel electrode of the light-emitting diode LED via the sixth transistor T6. The first terminal of the first transistor T1 may be connected to a second terminal of the fifth transistor T5. The second terminal of the first transistor T1 may be connected to the first terminal of the sixth transistor T6, the storage capacitor Cst, and the hold capacitor Chold. The first transistor T1 may be configured to control the amount of a driving current flowing to the light-emitting diode LED by receiving the data signal DATA in response to a switching operation of the second transistor T2.

The second transistor T2 may be connected to the data line DL and the gate of the first transistor T1. The second transistor T2 may include a gate connected to the first gate line GWL, a first terminal connected to the data line DL, and the second terminal connected to the first node N1. The second terminal of the second transistor T2 may be connected to the gate of the first transistor T1, the first terminal of the third transistor T3, and the storage capacitor Cst. The second transistor T2 may be turned on by the first gate signal GW transmitted through the first gate line GWL and may be configured to electrically connect the data line DL to the first node N1 and transmit to the first node N1, the data signal DATA transmitted through the data line DL.

The third transistor T3 may be connected to the gate of the first transistor T1 and the reference voltage line VRL. The third transistor T3 may include a gate connected to the second gate line GRL, the first terminal connected to the first node N1, and a second terminal connected to the reference voltage line VRL. The first terminal of the third transistor T3 may be connected to the gate of the first transistor T1, the second terminal of the second transistor T2, and the storage capacitor Cst. The third transistor T3 may be turned on by the second gate signal GR transmitted through the second gate line GRL and may be configured to transmit to the first node N1, the reference voltage Vref transmitted through the reference voltage line VRL.

The fourth transistor T4 may be connected to the sixth transistor T6 and the initialization voltage line VAL. The fourth transistor T4 may be connected between the light-emitting diode LED and the initialization voltage line VAL. The fourth transistor T4 may include a gate connected to the fourth gate line GIL, a first terminal connected to a third node N3, and a second terminal connected to the initialization voltage line VAL. The first terminal of the fourth transistor T4 may be connected to a second terminal of the sixth transistor T6 and the pixel electrode of the light-emitting diode LED. The fourth transistor T4 may be turned on by the fourth gate signal GI transmitted through the fourth gate line GIL and may be configured to transmit to the third node N3, the initialization voltage Vaint transmitted through the initialization voltage line VAL and initialize the pixel electrode (e.g., an anode) of the light-emitting diode LED.

The fifth transistor T5 may be connected to the driving voltage line PL and the first transistor T1. The fifth transistor T5 may include a gate connected to the third gate line EML, a first terminal connected to the driving voltage line PL, and a second terminal connected to the first terminal of the first transistor T1. The fifth transistor T5 may be turned on or turned off in response to the third gate signal EM transmitted through the third gate line EML.

The sixth transistor T6 may be connected to the first transistor T1 and the light-emitting diode LED. The sixth transistor T6 may be connected between the second node N2 and the third node N3. The sixth transistor T6 may include a gate connected to the fifth gate line EMBL, the first terminal connected to the second node N2, and the second terminal connected to the third node N3. The first terminal of the sixth transistor T6 may be connected to the second terminal of the first transistor T1, the storage capacitor Cst, and the hold capacitor Chold. The second terminal of the sixth transistor T6 may be connected to the first terminal of the fourth transistor T4 and the pixel electrode of the light-emitting diode LED. The sixth transistor T6 may be turned on or turned off in response to the fifth gate signal EMB transmitted through the fifth gate line EMBL.

The storage capacitor Cst may be connected between the gate of the first transistor T1 and the second terminal of the first transistor T1. A first electrode of the storage capacitor Cst may be connected to the first node N1, and a second electrode thereof may be connected to the second node N2. The first electrode of the storage capacitor Cst may be connected to the gate of the first transistor T1, the second terminal of the second transistor T2, and the first terminal of the third transistor T3. The second electrode of the storage capacitor Cst may be connected to the second terminal and the first-2 gate of the first transistor T1, a second electrode of the hold capacitor Chold, and the first terminal of the sixth transistor T6. The storage capacitor Cst may be configured to store a threshold voltage of the first transistor T1 and a voltage corresponding to the data signal DATA.

When the third transistor T3 and the fifth transistor T5 are turned on, the first transistor T1 may be turned on. When a voltage at the second terminal of the first transistor T1 drops to a difference (Vref−Vth1) between the reference voltage Vref and a threshold voltage Vth1 of the first transistor T1, the first transistor T1 is turned off, and a voltage corresponding to the threshold voltage Vth1 of the first transistor T1 is stored in the storage capacitor Cst such that the threshold voltage Vth1 of the first transistor T1 may be compensated for.

The hold capacitor Chold may be connected between the driving voltage line PL and the second node N2. A first electrode of the hold capacitor Chold may be connected to the driving voltage line PL. The second electrode of the hold capacitor Chold may be connected to the second terminal and the first-2 gate of the first transistor T1, the second electrode of the storage capacitor Cst, and the first terminal of the sixth transistor T6.

A capacitance of each of the storage capacitor Cst and the hold capacitor Chold may vary according to the color of light emitted from the light-emitting diode LED.

The auxiliary capacitor Ca may be electrically connected to the sixth transistor T6, a sustain voltage line VSSL, and the pixel electrode of the light-emitting diode LED. The auxiliary capacitor Ca may be configured to store and maintain a voltage corresponding to the difference between voltages of the pixel electrode of the light-emitting diode LED and the sustain voltage line VSSL, thereby preventing an increase in black luminance when the sixth transistor T6 is turned off.

The light-emitting diode LED may be connected to the first transistor T1 through the sixth transistor T6. The light-emitting diode LED may include the pixel electrode (or “anode”) connected to the third node N3 and an opposite electrode (or “cathode”) facing the pixel electrode, and the opposite electrode may be configured to receive the common voltage ELVSS. In an embodiment, the opposite electrode (or “cathode”) may extend into a display area and be electrically connected to the sustain voltage line VSSL configured to provide the common voltage ELVSS. The driving current output by the first transistor T1 may flow through the light-emitting diode LED in response to the turned-on fifth transistor T5 and the turned-on sixth transistor T6, and the light-emitting diode LED may be configured to emit light with a luminance corresponding to the magnitude of the driving current.

Although FIG. 7 illustrates that the pixel circuit PC includes six transistors, one or more embodiments are not necessarily limited thereto. In an embodiment, the pixel circuit PC may include seven transistors. In an embodiment, the number of transistors of the pixel circuit PC may be five or less or eight or more.

The pixel circuit PC of FIG. 7 may be a first pixel circuit PC1 configured to drive main subpixels arranged in a first display area or may be a second pixel circuit PC2 configured to drive auxiliary subpixels arranged in a second display area. In an embodiment, the first pixel circuits PC1 may be provided identically to the second pixel circuit PC2.

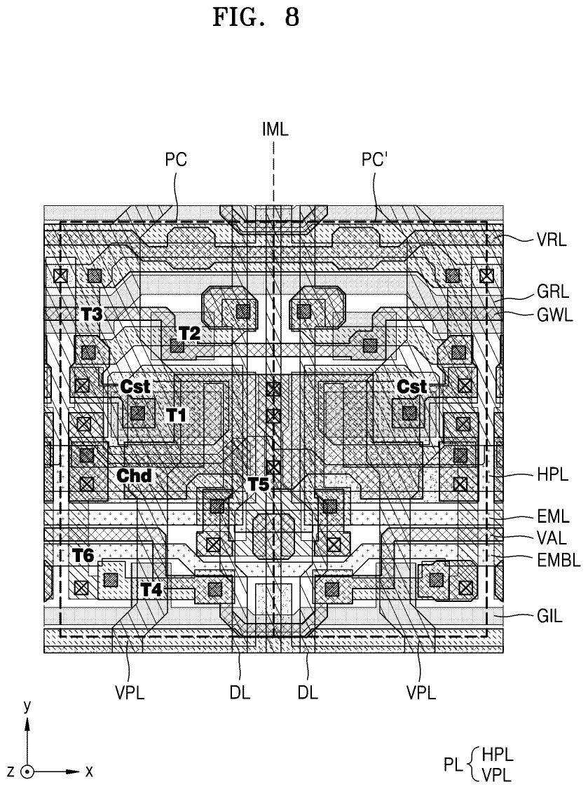

FIG. 8 is a schematic plan view of pixel circuits that may be arranged on a display panel, according to an embodiment. For convenience of description, FIG. 8 illustrates two pixel circuits PC and PC′ arranged in the same row in a first direction (e.g., an x-direction).

Referring to FIG. 8, the two adjacent pixel circuits PC and PC′ may each include transistors and capacitors. In an embodiment, each of the pixel circuits PC and PC′ may include the first to sixth transistors T1, T2, T3, T4, T5, and T6, the storage capacitor Cst, and the hold capacitor Chold, which have been described above with reference to FIG. 7.

The first to fourth transistors T1, T2, T3, and T4 may be provided as oxide semiconductors, and the fifth transistor T5 and the sixth transistor T6 may be provided as silicon semiconductors (e.g., polycrystalline silicon, amorphous silicon). Accordingly, the first to fourth transistors T1, T2, T3, and T4 may be arranged on the same layer. The fifth and sixth transistors T5 and T6 may be arranged on a different layer from the first to fourth transistors T1, T2, T3, and T4. The fifth transistor T5 and the sixth transistor T6 may be arranged on the same layer.

The transistors and the capacitors of the pixel circuit PC may be symmetrically arranged with transistors and capacitors of the pixel circuit PC′, respectively. For example, the first transistor T1 of the pixel circuit PC may be symmetrical with a first transistor T1 of the pixel circuit PC′ with respect to a virtual line IML passing between the pixel circuit PC and the pixel circuit PC′ in a second direction (e.g., a y-direction). Similarly, the second to sixth transistors T2, T3, T4, T5, and T6 and the storage capacitor Cst of the pixel circuit PC may be symmetrical with second to sixth transistors T2, T3, T4, T5, and T6 and a storage capacitor Cst of the pixel circuit PC′ with respect to the virtual line IML, respectively.

Moreover, some of the components of the pixel circuit PC may not be symmetrically arranged with those of the pixel circuit PC′. For example, the hold capacitor Chold of the pixel circuit PC and a hold capacitor Chold of the pixel circuit PC′ have different electrode structures and thus may not be arranged symmetrically.

Gate lines electrically connected to the pixel circuits PC and PC′, for example, the first gate line GWL, the second gate line GRL, the third gate line EML, the fourth gate line GIL, the fifth gate line EMBL, the reference voltage line VRL, and the initialization voltage line VAL, may extend in the first direction (e.g., the x-direction). In some embodiments, the reference voltage line VRL and the initialization voltage line VAL may extend in the second direction rather than the first direction.

The data line DL may extend in the second direction (e.g., the y-direction). Data lines DL may be respectively arranged in the pixel circuits PC and PC′ and may be symmetrical to each other with respect to the aforementioned virtual line IML.

The driving voltage line PL may include a horizontal driving voltage line HPL extending in the first direction and a vertical driving voltage line VPL extending in the second direction. The horizontal driving voltage line HPL and the vertical driving voltage line VPL may be arranged on different layers and connected to each other through a contact hole. Accordingly, the driving voltage line PL may be provided in a mesh structure.

One vertical driving voltage line VPL may be arranged for every two adjacent pixel circuits in the first direction. Accordingly, the vertical driving voltage line VPL may not be arranged in the pixel circuit PC, but may be arranged in the pixel circuit PC′.

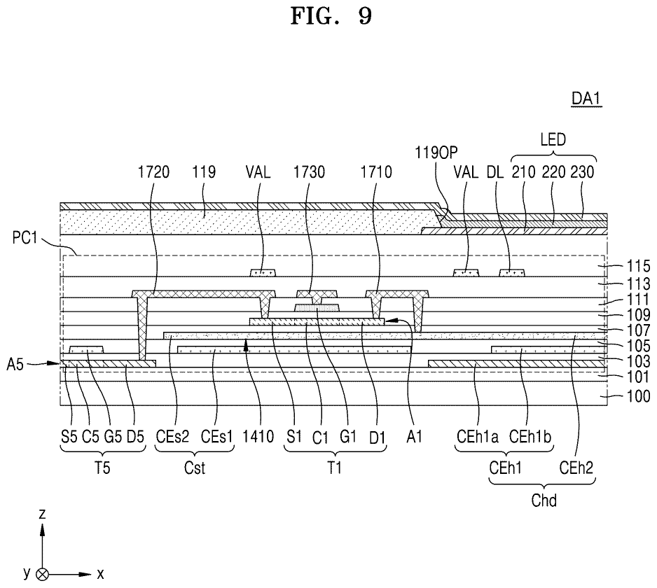

FIG. 9 is a schematic cross-sectional view illustrating a portion of a first display area DA1 of a display panel 10, according to an embodiment.

Referring to FIG. 9, the display panel 10 may include a circuit layer including transistors and capacitors arranged over the substrate 100, and a display element layer arranged on the aforementioned circuit layer and including the light-emitting diode LED. The circuit layer may include the transistors and the capacitors described above with reference to FIGS. 7 and 8, and FIG. 9 illustrates the first transistor T1 and the fifth transistor T5 of the first pixel circuits PC1, the storage capacitor Cst, and the hold capacitor Chd.

The first transistor T1 includes a first semiconductor layer A1 provided as an oxide semiconductor layer (e.g., Indium Gallium Zinc Oxide (IGZO), Indium Oxide (In₂O₃)), and a first gate electrode G1. The fifth transistor T5 includes a fifth semiconductor layer A5 provided as a silicon semiconductor layer, and a fifth gate electrode G5. The first transistor T1 and the fifth transistor T5 may be arranged on different layers.

The storage capacitor Cst may include a first storage electrode CEs1 and a second storage electrode CEs2 overlapping each other. A hold capacitor Chd may include a first hold electrode CEh1 and a second hold electrode CEh2 overlapping each other. The first hold electrode CEh1 may include sub-layers arranged on different layers, a first lower hold electrode CEh1a, and a first upper hold electrode CEh1b.

The substrate 100 may include a glass material, a ceramic material, a metal material, plastic, or a flexible or bendable material. When the substrate 100 is flexible or bendable, the substrate 100 may include polymer resin, such as polyethersulfone (PES), polyacrylate, polyetherimide (PEI), polyethylene naphthalate (PEN), polyethylene terephthalate (PET), polyphenylene sulfide (PPS), polyarylate, polyimide (PI), polycarbonate, or cellulose acetate propionate (CAP).

The substrate 100 may have a single-layered or multilayered structure of the above material, and when the substrate 100 has a multilayered structure, the substrate 100 may further include an inorganic layer. For example, the substrate 100 may have a structure in which a layer including the aforementioned polymer resin and a barrier layer including an inorganic insulating material are alternately stacked.

A buffer layer 101 may be arranged on the substrate 100. The buffer layer 101 may include an inorganic insulating layer including an inorganic insulating material, such as silicon nitride and/or silicon oxide, and may have a single-layered or multilayer structure including the aforementioned material.

A transistor including a silicon semiconductor layer may be arranged over the buffer layer 101. In this regard, FIG. 9 illustrates the fifth semiconductor layer A5 of the fifth transistor T5. The fifth semiconductor layer A5 may include polysilicon. The fifth semiconductor layer A5 may include a channel region C5 and impurity regions S5 and D5 arranged on both sides of the channel region C5 and doped with impurities. One of the impurity regions S5 and D5 of the fifth semiconductor layer A5 may be a source, and the other thereof may be a drain.

Also, a sub-layer of the first hold electrode CEh1 of the hold capacitor Chd, for example, the first lower hold electrode CEh1a, may be arranged over the buffer layer 101. The first lower hold electrode CEh1a and the fifth semiconductor layer A5 may be arranged on the same layer. The first lower hold electrode CEh1a may be formed by doping polysilicon with impurities.

A first gate insulating layer 103 arranged on the fifth semiconductor layer A5. The first gate insulating layer 103 may include an inorganic insulating layer including an inorganic insulating material, such as silicon oxide, silicon nitride, and/or silicon oxynitride, and may have a single-layered or multilayer structure including the aforementioned material.

The fifth gate electrode G5 may be arranged on the first gate insulating layer 103 and may overlap the channel region C5 of the fifth semiconductor layer A5. The first storage electrode CEs1 of the storage capacitor Cst and a sub-layer of the first hold electrode CEh1 of the hold capacitor Chd, for example, the first upper hold electrode CEh1b, may be arranged on the same layer as the fifth gate electrode G5, for example, on the first gate insulating layer 103.

The fifth gate electrode G5, the first storage electrode CEs1 of the storage capacitor Cst, and the first upper hold electrode CEh1b of the hold capacitor Chd may include the same material. The fifth gate electrode G5, the first storage electrode CEs1 of the storage capacitor Cst, and the first upper hold electrode CEh1b of the hold capacitor Chd may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may include a single layer or multilayer including the aforementioned material. In an embodiment, the fifth gate electrode G5, the first storage electrode CEs1 of the storage capacitor Cst, and the first upper hold electrode CEh1b of the hold capacitor Chd may include a single layer including Mo.

A second gate insulating layer 105 may be arranged on the fifth gate electrode G5, the first storage electrode CEs1 of the storage capacitor Cst, and the first upper hold electrode CEh1b of the hold capacitor Chd. The second gate insulating layer 105 may include an inorganic insulating layer including an inorganic insulating material, such as silicon oxide, silicon nitride, and/or silicon oxynitride, and may have a single-layered or multilayer structure including the aforementioned material. In an embodiment, the second gate insulating layer 105 and the first gate insulating layer 103 may include different materials. For example, the first gate insulating layer 103 may include silicon oxide, and the second gate insulating layer 105 may include silicon nitride.

A conductive layer 1410 may be arranged on the second gate insulating layer 105. The conductive layer 1410 may overlap the first storage electrode CEs1 of the storage capacitor Cst and the first upper hold electrode CEh1b of the hold capacitor Chd. The conductive layer 1410 may include the second storage electrode CEs2 of the storage capacitor Cst and the second hold electrode CEh2 of the hold capacitor Chd. A portion of the conductive layer 1410 may include the second storage electrode CEs2 of the storage capacitor Cst, and another portion of the conductive layer 1410 may include the second hold electrode CEh2 of the hold capacitor Chd. In other words, the second storage electrode CEs2 of the storage capacitor Cst and the second hold electrode CEh2 of the hold capacitor Chd may be integrally connected to each other.

The second hold electrode CEh2 of the hold capacitor Chd may overlap the first upper hold electrode CEh1b and the first lower hold electrode CEh1a disposed below the second hold electrode Ceh2. The first upper hold electrode CEh1b of the hold capacitor Chd may be electrically connected to the first lower hold electrode CEh1a.

The conductive layer 1410, for example, the second storage electrode CEs2 of the storage capacitor Cst and the second hold electrode CEh2 of the hold capacitor Chd, may include Al, Pt, Pd, Ag, Mg, Au, Ni, Nd, Ir, Cr, Li, Ca, Mo, Ti, W, and/or Cu, and may include a single layer or multilayer including the aforementioned material. In an embodiment, the conductive layer 1410 may include a single layer including Mo.

A first interlayer insulating layer 107 may be arranged on the conductive layer 1410. The first interlayer insulating layer 107 may include an inorganic insulating layer including an inorganic insulating material, such as silicon oxide, silicon nitride, and/or silicon oxynitride, and may have a single-layered or multilayer structure including the aforementioned material. For example, the first interlayer insulating layer 107 may have a stacked structure of a layer including silicon oxide and a layer including silicon nitride.

The first semiconductor layer A1 of the first transistor T1 may be arranged on the first interlayer insulating layer 107. The first semiconductor layer A1 of the first transistor T1 may include an oxide semiconductor, and the oxide semiconductor may include at least one element selected from the group consisting of indium (In), gallium (Ga), tin (Sn), zirconium (Zr), vanadium (V), hafnium (Hf), cadmium (Cd), germanium (Ge), Cr, Ti, Al, cesium (Cs), cerium (Ce), and zinc (Zn). For example, the oxide semiconductor may include InSnZnO (ITZO) or InGaZnO (IGZO).

The first semiconductor layer A1 may include a channel region C1 and conductive regions S1 and D1 arranged on both sides of the channel region C1. One of the conductive regions S1 and D1 may be a source, and the other thereof may be a drain.

The first semiconductor layer A1 and the aforementioned fifth semiconductor layer A5 may be arranged on different layers. A vertical distance from the substrate 100 to the first semiconductor layer A1 may be greater than a vertical distance from the substrate 100 to the fifth semiconductor layer A5.

A third gate insulating layer 109 may be arranged on the first semiconductor layer A1. The third gate insulating layer 109 may include an inorganic insulating layer including an inorganic insulating material, such as silicon oxide, silicon nitride, and/or silicon oxynitride, and may have a single-layered or multilayer structure including the aforementioned material. In an embodiment, the third gate insulating layer 109 may include a single layer including silicon oxide.

Although FIG. 9 illustrates that the third gate insulating layer 109 passes through the sides (or “covers sidewalls”) of the first semiconductor layer A1 and comes into contact with the upper surface of the first interlayer insulating layer 107, one or more embodiments are not necessarily limited thereto. In an embodiment, the third gate insulating layer 109 may be formed to have substantially the same pattern and/or the same width as the first gate electrode G1 to be described below. In other words, the third gate insulating layer 109 may not pass through the sides of the first semiconductor layer A1 and come into contact with the upper surface of the first interlayer insulating layer 107.

The first gate electrode G1 may be arranged on the third gate insulating layer 109. The first gate electrode G1 may overlap the channel region C1 of the first semiconductor layer A1. The first gate electrode G1 may include Al, Pt, Pd, Ag, Mg, Au, Ni, Nd, Ir, Cr, Li, Ca, Mo, Ti, W, and/or Cu and may include a single layer or multilayer including the aforementioned material. In an embodiment, the first gate electrode G1 may have a three-layer structure of a Ti layer, an Al layer, and a Ti layer.

A second interlayer insulating layer 111 may be arranged on the first gate electrode G1. The second interlayer insulating layer 111 may include an inorganic insulating layer including an inorganic insulating material, such as silicon oxide, silicon nitride, and/or silicon oxynitride, and may have a single-layered or multilayer structure including the aforementioned material. In an embodiment, the second interlayer insulating layer 111 may have a stacked structure of a layer including silicon nitride and a layer including silicon oxynitride.

A first connection electrode 1710, a second connection electrode 1720, and a third connection electrode 1730 may be arranged on the second interlayer insulating layer 111. The first connection electrode 1710, the second connection electrode 1720, and the third connection electrode 1730 may include the same material. The first connection electrode 1710, the second connection electrode 1720, and the third connection electrode 1730 may include Al, Pt, Pd, Ag, Mg, Au, Ni, Nd, Ir, Cr, Li, Ca, Mo, Ti, W, and/or Cu, and may include a single layer or multilayer including the aforementioned material. In an embodiment, the first connection electrode 1710, the second connection electrode 1720, and the third connection electrode 1730 may have a three-layer structure of a Ti layer, an Al layer, and a Ti layer.

The first connection electrode 1710 may connect a conductive region D1 of the first semiconductor layer A1 to the conductive layer 1410. The second connection electrode 1720 may connect a conductive region S1 of the first semiconductor layer A1 to a conductive region D5 of the fifth semiconductor layer A5. The third connection electrode 1730 may connect the first gate electrode G1 to another transistor.

A first organic insulating layer 113 may be arranged on the first connection electrode 1710, the second connection electrode 1720, and the third connection electrode 1730. The first organic insulating layer 113 may include an organic insulating material, such as acryl, benzocyclobutene (BCB), PI, or hexamethyldisiloxane (HMDSO).

The data line DL and initialization voltage lines VAL may be arranged on the first organic insulating layer 113. The data line DL and the initialization voltage lines VAL may each include Al, Pt, Pd, Ag, Mg, Au, Ni, Nd, Ir, Cr, Li, Ca, Mo, Ti, W, and/or Cu and may include a single layer or multilayer including the aforementioned material. In an embodiment, the data line DL and the initialization voltage lines VAL may each have a three-layer structure of a Ti layer, an Al layer, and a Ti layer.

A second organic insulating layer 115 may be arranged on the data line DL and the initialization voltage lines VAL. The second organic insulating layer 115 may include an organic insulating material, such as acryl, BCB, PI, or HMDSO.

The light-emitting diode LED may be arranged on the second organic insulating layer 115. The light-emitting diode LED may include a pixel electrode 210, an intermediate layer 220, and an opposite electrode 230 over the second organic insulating layer 115.

An outer portion of the pixel electrode 210 may be covered by a bank layer 119, and an inner portion of the pixel electrode 210 may overlap the intermediate layer 220 through an opening 119OP of the bank layer 119. The pixel electrode 210 may be arranged to correspond to each light-emitting diode LED, and the opposite electrode 230 may be arranged to correspond to a plurality of light-emitting diodes LED. In other words, the opposite electrode 230 may extend to overlap a plurality of pixel electrodes 210. The plurality of light-emitting diodes LED may share the opposite electrode 230, and a stacked structure of the pixel electrode 210, the intermediate layer 220, and the opposite electrode 230 may correspond to the light-emitting diode LED.

The intermediate layer 220 may include an emission layer. In some embodiments, the intermediate layer 220 may further include an emission layer and a functional layer. The functional layer may include a hole transport layer (HTL), a hole injection layer (HIL), an electron transport layer (ETL), and/or an electron injection layer (EIL). In an embodiment, the intermediate layer 220 may include a first stack including an emission layer and a functional layer, a second stack including an emission layer and a functional layer, and a charge generation layer between the first stack and the second stack. The charge generation layer may include a negative charge generation layer and a positive charge generation layer. The light emission efficiency of a tandem-type light-emitting diode LED including a plurality of emission layers may be further increased by the negative charge generation layer and the positive charge generation layer.

The negative charge generation layer may be an n-type charge generation layer. The negative charge generation layer may be configured to supply electrons. The negative charge generation layer may include a host and a dopant. The host may include an organic material. The dopant may include a metal material. The positive charge generation layer may be a p-type charge generation layer. The positive charge generation layer may be configured to supply holes. The positive charge generation layer may include a host and a dopant. The host may include an organic material. The dopant may include a metal material.

The opposite electrode 230 may include a conductive material having a small work function. The opposite electrode 230 may include a (semi-)transparent layer including Ag, Mg, Al, Pt, Pd, Au, Ni, Nd, Ir, Cr, Li, Ca, or any alloys thereof. Alternatively, the opposite electrode 230 may further include a layer, such as indium tin oxide (ITO), indium zinc oxide (IZO), zinc oxide (ZnO), or indium oxide (In₂O₃), on the (semi-)transparent layer including the above material.

An encapsulation layer may be arranged over the light-emitting diode LED. The encapsulation layer may include a first inorganic encapsulation layer, a second inorganic encapsulation layer, and an organic encapsulation layer therebetween.

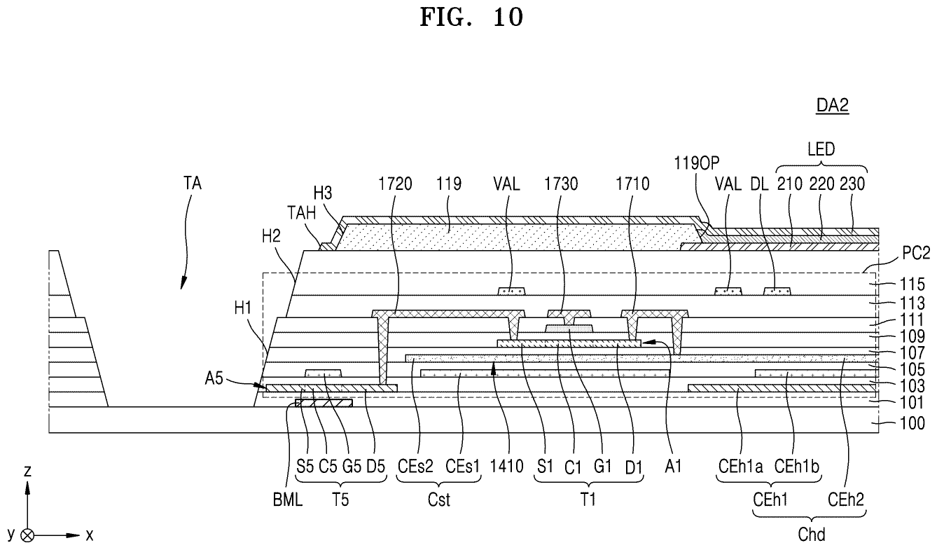

FIG. 10 is a schematic cross-sectional view illustrating a portion of a second display area DA2 of a display panel, according to an embodiment.

The transparent area TA and the second pixel circuit PC2 may be arranged in the second display area DA2. FIG. 10 illustrates the first transistor T1 and the fifth transistor T5 of the second pixel circuit PC2, the storage capacitor Cst, and the hold capacitor Chold. The description of the configuration of the second pixel circuit PC2 is replaced with the description of the configuration of the first pixel circuit PC1 of FIG. 9.

Referring to FIG. 10, the bottom metal layer BML may be arranged in the second display area DA2. The bottom metal layer BML may be arranged on the substrate 100. The bottom metal layer BML may include one or more materials selected from among Al, Pt, Pd, Ag, Mg, Au, Ni, Nd, Ir, Cr, Li, Ca, Mo, Ti, W, and Cu. In some embodiments, the bottom metal layer BML may include a single layer including Mo, or may have a two-layer structure in which a Mo layer and a Ti layer are stacked or a three-layer structure in which a Ti layer, an Al layer, and a Ti layer are stacked.

The bottom metal layer BML may have a voltage level corresponding to a constant voltage. For example, the bottom metal layer BML may have the same voltage level (e.g., the driving voltage ELVDD) as the driving voltage line PL described above with reference to FIG. 7. Alternatively, the bottom metal layer BML may be configured to receive a separate constant voltage differently from the driving voltage line.

Alternatively, the bottom metal layer BML may be configured to provide the same signal as the fifth gate electrode G5. In this case, the bottom metal layer BML may function as a lower gate electrode. The bottom metal layer BML may be configured to shield light traveling toward the fifth semiconductor layer A5 of the fifth transistor T5 and protect the fifth transistor T5 from electrostatic discharge (ESD). The bottom metal layer BML may be connected to a power supply line in an area other than a display area, for example, a peripheral area.

The bottom metal layer BML may overlap a transistor including a silicon semiconductor layer. FIG. 10 illustrates that the bottom metal layer BML overlaps the fifth transistor T5, but the bottom metal layer BML may overlap the sixth transistor T6 (see FIG. 8) including a silicon semiconductor layer.

In the present embodiment, because components configured to emit and receive light may be arranged below the second display area DA2, the bottom metal layer BML is arranged to protect light-sensitive transistors from light. Transistors including a silicon semiconductor layer may have characteristics that change due to external light, especially infrared light, and thus, the bottom metal layer BML according to the present embodiment may overlap the transistors including the silicon semiconductor layer.

However, the bottom metal layer BML does not overlap the entire silicon semiconductor layer. For example, the bottom metal layer BML may entirely overlap a channel region C5 of the fifth transistor T5, but may not overlap a portion of conductive regions S5 and D5. Also, the bottom metal layer BML may not overlap the first transistor T1 including an oxide semiconductor layer.

Because light may also transmit through an area of the second display area DA2 where the second pixel circuit PC2 is arranged, the light transmittance of the second display area DA2 may be reduced by the area occupied by the bottom metal layer BML in the second display area DA2. The bottom metal layer BML according to the present embodiment is arranged to protect the transistors including the silicon semiconductor layer while taking into account the light transmittance of the second display area DA2. Thus, by minimizing an area in a plan view occupied by the bottom metal layer BML, both goals of improving electronic stability and maximizing light transmittance can be achieved.

The transparent area TA is arranged in the second display area DA2. The transparent area TA may be an area of the second display area DA2 where the components of the second pixel circuit PC2 are not arranged, and may be an area having high light transmittance.

When the first gate insulating layer 103, the second gate insulating layer 105, the first interlayer insulating layer 107, the third gate insulating layer 109, and the second interlayer insulating layer 111 are collectively referred to as inorganic insulating layers, the inorganic insulating layers may include a first hole H1 corresponding to the transparent area TA. The first hole H1 may expose a portion of the upper surface of the buffer layer 101 or the substrate 100. The first hole H1 may be formed by overlapping an opening of a first gate insulating layer 103, an opening of the second gate insulating layer 105, an opening of the first interlayer insulating layer 107, an opening of the third gate insulating layer 109, and an opening of the second interlayer insulating layer 111, which are formed to correspond to the transparent area TA. These openings may be formed individually through separate processes or simultaneously through the same process. When these openings are formed through separate processes, the inner surface of the first hole H1 may not be smooth and may have steps in the shape of staircases.

In contrast, the inorganic insulating layers may include a groove other than the first hole H1 exposing the buffer layer 101. Alternatively, the inorganic insulating layers may not include the first hole H1 or groove corresponding to the transparent area TA. The inorganic insulating layers generally include an inorganic insulating material having excellent light transmittance and thus may have sufficient transmittance even without a hole or groove corresponding to the transparent area TA, thereby allowing the component 40 (see FIG. 2) to transmit/receive a sufficient amount of light.

The first organic insulating layer 113 and the second organic insulating layer 115 may include a second hole H2 corresponding to the transparent area TA. The second hole H2 may overlap the first hole H1. FIG. 10 illustrates that the second hole H2 is formed greater than the first hole H1. In an embodiment, the first organic insulating layer 113 and the second organic insulating layer 115 is provided to cover the edge of the first hole H1 of the inorganic insulating layers such that the area of the second hole H2 may be formed smaller than the area of the first hole H1.

The bank layer 119 may include a third hole H3 arranged in the transparent area TA. The third hole H3 may overlap the first hole H1 and the second hole H2. The light transmittance of the transparent area TA may be improved by the first hole H1 to the third hole H3. Moreover, FIG. 10 illustrates that the buffer layer 101 may include a hole arranged in the transparent area TA, but the buffer layer 101 may instead be continuously arranged to correspond to the transparent area TA. A portion of the opposite electrode 230 may be arranged on the inner surfaces of the first hole H1 to the third hole H3.

The opposite electrode 230 may include a through-hole TAH corresponding to the transparent area TA. When the through-hole TAH corresponds to the transparent area TA, it may be understood that the through-hole TAH overlaps the transparent area TA.

Due to the through-hole TAH, a portion of the opposite electrode 230 is not present in the transparent area TA, and accordingly, the light transmittance of the transparent area TA may be significantly increased. The opposite electrode 230 including the through-hole TAH may be formed by using various methods. In an embodiment, after a material for forming the opposite electrode 230 is formed on the entire surface of the substrate 100, a portion corresponding to the transparent area TA may be removed by using laser lift-off, thereby forming the opposite electrode 230 including the through-hole TAH. In an embodiment, the opposite electrode 230 including the through-hole TAH may be formed by using a metal self-patterning (MSP) method. In an embodiment, the opposite electrode 230 including the through-hole TAH may be formed by depositing the opposite electrode 230 using a fine metal mask (FMM).

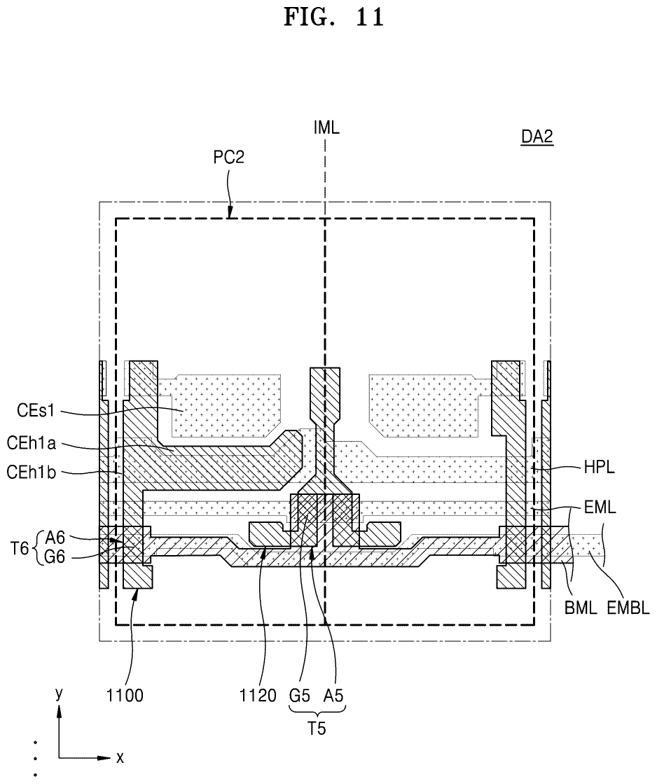

FIG. 11 is a layout view illustrating the arrangement of a bottom metal layer BML and some components of a second pixel circuit PC2 that may be arranged in a second display area DA2, according to an embodiment.

Referring to FIG. 11, the arrangement of the bottom metal layer BML, silicon semiconductor layers 1100 and 1120, and a first gate electrode layer, which are arranged over the second display area DA2 of the substrate 100, is shown.

The silicon semiconductor layers 1100 and 1120 may include a first silicon semiconductor layer 1100 and a second silicon semiconductor layer 1120. The first silicon semiconductor layer 1100 and the second silicon semiconductor layer 1120 may be arranged on the same layer and spaced apart from each other. The first silicon semiconductor layer 1100 may include a sixth semiconductor layer A6 of the sixth transistor T6 and the first lower hold electrode CEh1a of the hold capacitor Chd. The second silicon semiconductor layer 1120 may include the fifth semiconductor layer A5 of the fifth transistor T5.

The first gate electrode layer may include the third gate line EML, the fifth gate line EMBL, the horizontal driving voltage line HPL, and first storage electrode CEs1 of the storage capacitor Cst, which are arranged on the same layer and spaced apart from each other.

The third gate line EML may extend in an x-direction and include the fifth gate electrode G5 overlapping the fifth semiconductor layer A5. The fifth semiconductor layer A5 and the fifth gate electrode G5 may form the fifth transistor T5.

The fifth gate line EMBL may extend in the x-direction and include a sixth gate electrode G6 overlapping the sixth semiconductor layer A6. The sixth semiconductor layer A6 and the sixth gate electrode G6 may form the sixth transistor T6.

The horizontal driving voltage line HPL may extend in the x-direction and include the first upper hold electrode CEh1b of the hold capacitor Chd. The first upper hold electrode CEh1b may include an area overlapping the first lower hold electrode CEh1a provided in the first silicon semiconductor layer 1100 therebelow. The first storage electrode CEs1 of the storage capacitor Cst may overlap a portion of the first silicon semiconductor layer 1100.

The bottom metal layer BML may be arranged below the first and second silicon semiconductor layers 1100 and 1120 and overlap a portion of the first and second silicon semiconductor layers 1100 and 1120. The bottom metal layer BML may overlap the sixth semiconductor layer A6 and the fifth semiconductor layer A5. The bottom metal layer BML may be arranged to extend in the x-direction and include a protrusion overlapping the fifth semiconductor layer A5 and protruding in a y-direction. The bottom metal layer BML may overlap the fifth gate line EMBL. The bottom metal layer BML may overlap the fifth gate electrode G5, which is a portion of the third gate line EML.

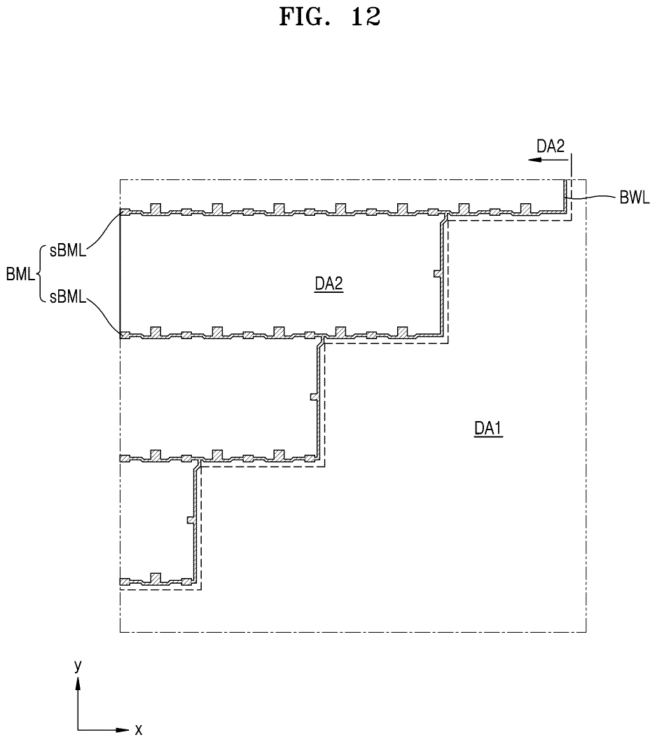

FIG. 12 is a plan view of a bottom metal layer BML arranged at a boundary between a first display area DA1 and a second display area DA2, according to an embodiment.

Referring to FIG. 12, the bottom metal layer BML may be arranged in the second display area DA2 and may not be arranged in the first display area DA1.

The bottom metal layer BML may be arranged to intersect the second display area DA2 in a first direction (x-direction). The bottom metal layer BML may include plurality of sub-bottom metal layers sBML. The sub-bottom metal layers sBML may be provided to extend in the first direction (x-direction) inside the second display area DA2. The plurality of sub-bottom metal layers sBML may be arranged to be spaced apart from each other at a certain interval in a second direction (y-direction). The plurality of sub-bottom metal layers sBML may be connected to each other by a bottom connection line BWL at the edge of the second display area DA2. The bottom connection line BWL and the bottom metal layer BML may be arranged on the same layer and integrally provided as a single body so that they have an uninterrupted shape. The bottom connection line BWL may extend to a peripheral area of a display panel and receive a constant voltage or a signal.

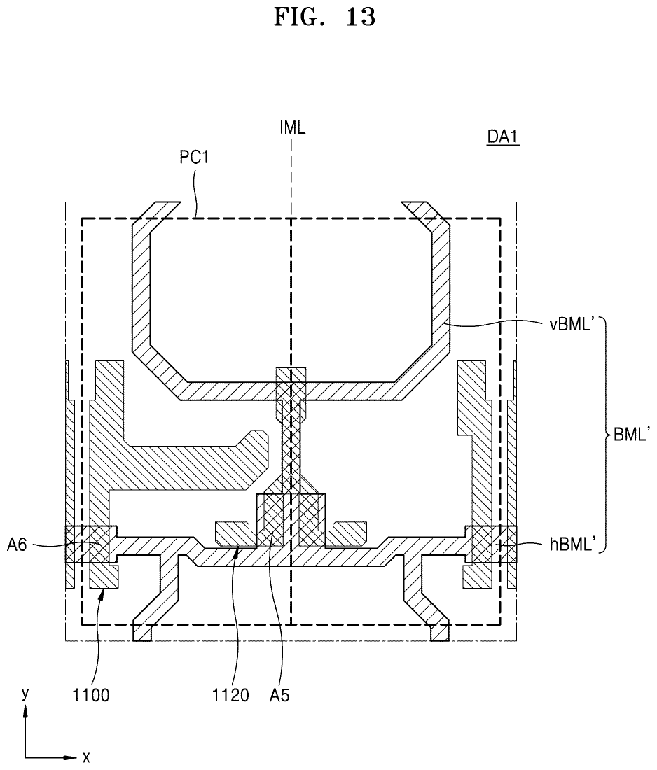

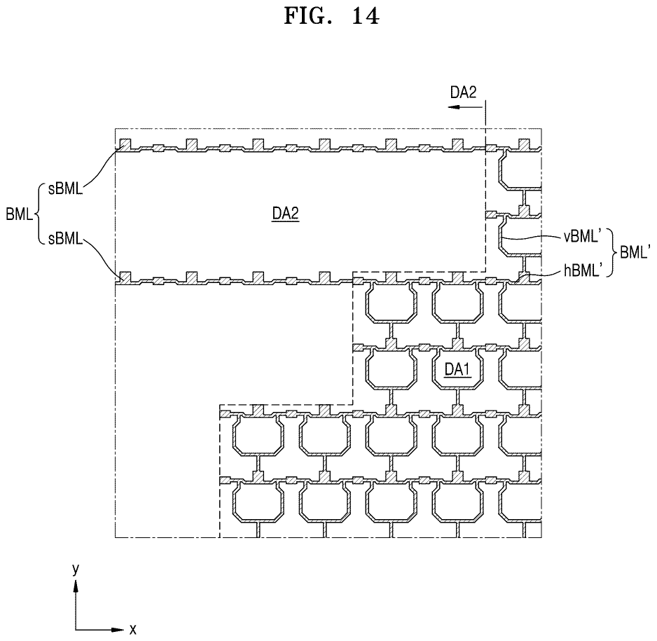

In FIG. 12, the bottom metal layer BML is not arranged in the first display area DA1, but one or more embodiments are not necessarily limited thereto. As shown in FIGS. 13 and 14 to be described below, an additional bottom metal layer connected to the bottom metal layer BML may be further arranged in the first display area DA1.

FIG. 13 is a layout view illustrating the arrangement of an additional bottom metal layer BML′ and some components of a first pixel circuit PC1 that may be arranged in a first display area DA1, according to an embodiment.

Referring to FIG. 13, the arrangement of the additional bottom metal layer BML′ and the first and second silicon semiconductor layers 1100 and 1120, which are arranged over the first display area DA1 of the substrate 100, is shown.

The additional bottom metal layer BML′ may be arranged below the silicon semiconductor layers 1100 and 1120, e.g., the first silicon semiconductor layer 1100 and the second silicon semiconductor layer 1120, included in the first pixel circuit PC1, and may overlap a portion of the first silicon semiconductor layer 1100 and the second silicon semiconductor layer 1120.

The additional bottom metal layer BML′ may include a horizontal bottom metal layer hBML′ extending in the x-direction and a vertical bottom metal layer vBML′ extending in the y-direction. The horizontal bottom metal layer hBML′ may overlap the sixth semiconductor layer A6. The vertical bottom metal layer vBML′ may overlap the fifth semiconductor layer A5 included in two adjacent first pixel circuits PC1 and may be divided into two branches and extend in the y-direction. The two branches of the vertical bottom metal layer vBML′ may extend in the y-direction and be connected to a horizontal bottom metal layer of the first pixel circuit PC1 arranged in a previous row. The horizontal bottom metal layer hBML′ and the vertical bottom metal layer vBML′ may be integrally provided as a single body and form a mesh structure.

The characteristics of the first and second silicon semiconductor layers 1100 and 1120 arranged in the first display area DA1 may also be affected by external light, and thus, the additional bottom metal layer BML′ may be provided to stabilize the characteristics of the first pixel circuit PC1.

Thus, like the second display area DA2, the silicon semiconductor layers disposed in the first display area DA1 may overlap bottom metal layers BML′ so that they can be shielded from light and therefore improve electrical stability. Further, an area in a plan view occupied by the bottom metal layer BML′ may be minimized to minimize a reduction in luminance and transparency.

FIG. 14 is a plan view of a bottom metal layer arranged at a boundary between a first display area DA1 and a second display area DA2, according to an embodiment.

Referring to FIG. 14, the bottom metal layer BML may be arranged in the second display area DA2, and the additional bottom metal layer BML′ may be arranged in the first display area DA1. In a plan view, the additional bottom metal layer BML′ may be provided in a different shape from the bottom metal layer BML.

The bottom metal layer BML may be arranged to intersect the second display area DA2 in the first direction (x-direction). The bottom metal layer BML may include plurality of sub-bottom metal layers sBML. The sub-bottom metal layers sBML may be provided to extend in the first direction (x-direction) inside the second display area DA2. The plurality of sub-bottom metal layers sBML may be arranged to be spaced apart from each other at a certain interval in the second direction (y-direction).

The additional bottom metal layer BML′ may include a plurality of horizontal bottom metal layers hBML′ extending in the x-direction and a plurality of vertical bottom metal layers vBML′ extending in the y-direction. The horizontal bottom metal layer hBML′ may be arranged on the same line as the sub-bottom metal layer sBML arranged in the second display area DA2. The vertical bottom metal layer vBML′ may include two branches branching off in the y-direction from the horizontal bottom metal layer hBML′. The vertical bottom metal layer vBML′ may be connected to the horizontal bottom metal layer hBML′ arranged in a different row and form a mesh structure.

The bottom metal layer BML and the additional bottom metal layer BML′ may be integrally formed as a single body. The additional bottom metal layer BML′ is arranged in the first display area DA1, and accordingly, the overall resistance value of the bottom metal layer BML and the additional bottom metal layer BML′ may be lowered, and a voltage drop phenomenon may be significantly reduced.

Thus, the bottom metal layer BML of the second display area DA2 and the bottom metal layer BML′ of the first display area DA1 may have an uninterrupted (or “integral”) shape. Specifically, the horizontal bottom metal layer hBML′ of the first display area DA1 may be arranged in a same line as the sub-bottom metal layer sBML in the second display area DA2.

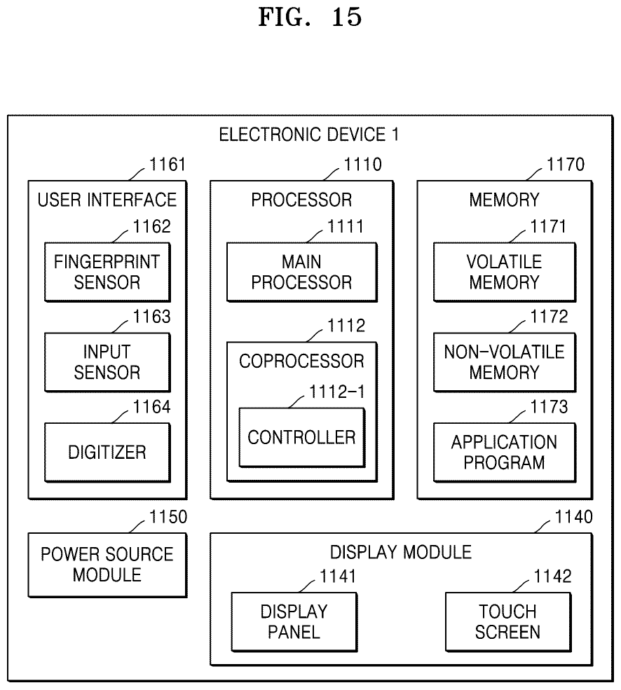

FIG. 15 is a diagram illustrating the electronic device according to an embodiment of the present invention. Referring to FIG. 15, the electronic device 1 according to one embodiment of the present disclosure may output various information (e.g., images, text, music, etc.) through a display panel 1141, which, for example, may correspond to the display panel 10 shown in FIG. 3 and may include an under panel camera (UPC) display panel. When a processor 1110 executes an application stored in a memory 1170, the display module 1140 may provide application information to a user through a display panel 1141.

In some embodiments, the electronic device 1 may be configured as a smartphone, camera, smart TV, monitor, smartwatch, tablet, automotive display, or AR/VR headset. For example, the electronic device 1 may be a smartphone including a touch-sensitive display area DA for interaction and a non-display area NDA including sensors and circuits for enhanced functionality. For example, the electronic device 1 may be a television or monitor including a large display area DA for high-resolution video playback and a non-display area NDA incorporating driving circuits or connectivity modules for external inputs. For example, the electronic device 1 may be a smartwatch including a display area DA optimized for compact and high-clarity visuals and a non-display area NDA integrating biometric sensors for health monitoring. In some cases, the electronic device 1 be an AR/VR headset.

In some embodiments, memory 1170 may store information such as software codes for operating an application program 1173. The application program 1173 may include a software designed to execute specific tasks or provide functionality to a user. The application program 1173 may operate under the control of the processor 1110 and utilizes data stored in the memory 1170 to deliver a wide range of features, such as productivity tools, multimedia streaming and playback, file or mail deliveries or communication services. The application program 1173 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1173 corresponding to the selected application retrieved from the memory 1170 to perform functionalities of the application. For example, when a user selects a camera application by tapping the icon (or “a camera application icon”) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1170. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1173.

The memory 1170 may store one or more application programs 1173 and various data used by at least one component (for example, the processor 1110 or the user interface 1161) of the electronic device 1 and input data or output data for commands related thereto. For example, a camera application program, a GPS application program, an augmented reality and virtual reality application program, and other application programs that can be executed by the processor 1110 upon selection of corresponding icons presented on the display screen (or “display panel 1141”) via the touch screen 1142 or user interface 1161 by the user. In addition, various setting data corresponding to user settings may be stored in the memory 1170. The memory 1170 may include volatile memory 1171 and non-volatile memory 1172.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display panel shown in FIG. 3.

The user interface 1161 serves as the interaction medium between a user and the electronic device 1. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1.

The display panel 1141 (or “display”) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display panel 10 shown in FIG. 1.

The power source module 1150 may supply power to the components of the electronic device 1. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

In the present specification, the additional bottom metal layer BML′ may be referred to as a first bottom metal layer BML′, and the bottom metal layer BML may be referred to as a second bottom metal layer BML. A shape of the first bottom metal layer BML′ may be provided differently from a shape of the second bottom metal layer BML in a plan view. The first bottom metal layer BML′ and the second bottom metal layer BML may be integrally provided as a single body.

As described above, the one or more embodiments have been described with reference to the accompanying drawings, but the embodiments should be considered in a descriptive sense only. Those of ordinary skill in the art will understand that various modifications and changes to the embodiments may be made therefrom. Therefore, the true technical scope of protection of the disclosure should be defined by the technical spirit of the appended claims.

As described above, an optimal bottom metal layer may be included in a second display area including a transmission area, thereby stabilizing the characteristics of a second pixel circuit arranged in the second display area and simultaneously securing the transmittance of the second display area.

However, the scope of the embodiments is not necessarily limited to the above effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display panel comprising:
a substrate including a first display area and a second display area, the second display area includes a transmission area;
a plurality of first pixel circuits and a plurality of first light-emitting diodes disposed in the first display area;
a plurality of second pixel circuits disposed in the second display area and each including a first transistor and a second transistor, the first transistor including an oxide semiconductor, and the second transistor including a silicon semiconductor;
a plurality of second light-emitting diodes disposed in the second display area and respectively connected to the plurality of second pixel circuits; and
a bottom metal layer disposed in the second display area and between the substrate and the second transistor,
wherein the bottom metal layer overlaps the second transistor of each of the plurality of second pixel circuits and extends across the second display area in a first direction.

2. The display panel of claim 1, wherein
the bottom metal layer includes a plurality of sub-bottom metal layers,
the plurality of sub-bottom metal layers are spaced apart from each other in a second direction inside the second display area, and
the second direction intersects the first direction.

3. The display panel of claim 2, wherein the plurality of sub-bottom metal layers are connected to each other at an edge of the second display area.

4. The display panel of claim 1, wherein the bottom metal layer does not overlap the first transistor in a plan view.

5. The display panel of claim 1, wherein the plurality of second pixel circuits are continuously disposed in the second display area in the first direction.

6. The display panel of claim 5, wherein
the transmission area includes a plurality of sub-transmission areas,
the plurality of second pixel circuits and the plurality of sub-transmission areas are alternately disposed in a second direction intersecting the first direction.

7. The display panel of claim 1, wherein
the first transistor includes a driving transistor, and
the second transistor includes an emission control transistor connected to a pixel electrode of each of the plurality of second light-emitting diodes.

8. The display panel of claim 1, further comprising an additional bottom metal layer disposed in the first display area and between the substrate and each of the plurality of first pixel circuits.

9. The display panel of claim 8, wherein
the additional bottom metal layer is provided in a mesh structure connected in the first direction and a second direction in the first display area, and
the second direction intersects the first direction.

10. The display panel of claim 8, wherein
the plurality of first pixel circuits each including a first transistor and a second transistor,
the additional bottom metal layer overlaps in a plan view the second transistor included in each of the plurality of first pixel circuits, and
the second transistor includes a silicon semiconductor.

11. A display panel comprising:
a substrate including a first display area and a second display area, the second display area includes a transmission area;
a plurality of first pixel circuits and a plurality of first light-emitting diodes disposed in the first display area;
a plurality of second pixel circuits disposed in the second display area and each including a first transistor and a second transistor, the first transistor including an oxide semiconductor, and the second transistor including a silicon semiconductor;
a plurality of second light-emitting diodes disposed in the second display area and respectively connected to the plurality of second pixel circuits;
a first bottom metal layer disposed in the first display area and between the substrate and each of the plurality of first pixel circuits; and
a second bottom metal layer disposed in the second display area and between the substrate and each of the plurality of second pixel circuits,
wherein a shape of the first bottom metal layer is different from a shape of the second bottom metal layer in a plan view.

12. The display panel of claim 11, wherein
the second bottom metal layer overlaps the second transistor of each of the plurality of second pixel circuits in a plan view, and
the second bottom metal layer extends across the second display area in a first direction.

13. The display panel of claim 12, wherein
the first bottom metal layer includes a horizontal bottom metal layer and a vertical bottom metal layer,
the horizontal bottom metal layer intersects the first display area in the first direction,
the vertical bottom metal layer extends in a second direction that intersects the first direction, and
the horizontal bottom metal layer is continuously disposed with the second bottom metal layer.

14. The display panel of claim 11, wherein
the first bottom metal layer includes a plurality of horizontal bottom metal layers and a plurality of vertical bottom metal layers disposed in a mesh structure,
the plurality of horizontal bottom metal layers extending in a first direction, and
the plurality of vertical bottom metal layers extends in a second direction that intersects the first direction.

15. The display panel of claim 14, wherein
each of the plurality of first pixel circuits includes a first transistor and a second transistor,
the first transistor being provided as a silicon semiconductor,
the second transistor being provided as an oxide semiconductor, and
each of the plurality of horizontal bottom metal layers overlaps the first transistor of each of the plurality of first pixel circuits.

16. An electronic device comprising:
a display panel; and
a lower cover forming an exterior of the electronic device and including an opening in a front surface of the lower cover, the opening exposing a portion of the display panel,
wherein the display panel comprises:
a substrate including a first display area and a second display area, the second display area includes a transmission area;
a plurality of first pixel circuits and a plurality of first light-emitting diodes disposed in the first display area;
a plurality of second pixel circuits disposed in the second display area and each including a first transistor and a second transistor, the first transistor including an oxide semiconductor, and the second transistor including a silicon semiconductor;
a plurality of second light-emitting diodes disposed in the second display area and respectively connected to the plurality of second pixel circuits; and
a bottom metal layer disposed in the second display area and between the substrate and the second transistor,
wherein the bottom metal layer overlaps the second transistor of each of the plurality of second pixel circuits and extends across the second display area in a first direction.

17. The electronic device of claim 16, wherein
the bottom metal layer includes a plurality of sub-bottom metal layers,
the plurality of sub-bottom metal layers are disposed to be spaced apart from each other in a second direction inside the second display area, and
the second direction intersects the first direction.

18. The electronic device of claim 17, wherein the plurality of sub-bottom metal layers are connected to each other at an edge of the second display area.

19. The electronic device of claim 16, wherein the bottom metal layer does not overlap the first transistor in a plan view.

20. The electronic device of claim 16, further comprising an additional bottom metal layer disposed in the first display area and between the substrate and each of the plurality of first pixel circuits.
